(19) United States
(12) Patent Application Publication
(10) Pub. No.: US 2025/0057007 A1
(43) Pub. Date: Feb. 13, 2025

(54) LIGHT-EMITTING DEVICE AND PRODUCTION METHOD THEREFOR

(71) Applicant: Sharp Display Technology Corporation, Kameyama City, Mie (JP)

(72) Inventors: Kota ADACHI, Kameyama City, Mie (JP); Yasushi ASAOKA, Kameyama City, Mie (JP)

(21) Appl. No.: 18/721,677

(22) PCT Filed: Feb. 14, 2022
(86) PCT No.: PCT/JP2022/005676

§ 371 Date: Jun. 19, 2024

(51) Int. Cl. H10K 59/00; H10K 50/16; H10K 59/122; H10K 59/35

(52) U.S. Cl. CPC H10K 59/771; H10K 50/16; H10K 59/122; H10K 59/35

(57) ABSTRACT

A light-emitting device includes at least one light-emitting element including a first electrode and a second electrode facing each other, and a light-emitting layer provided between the first electrode and the second electrode. At least one of the light-emitting elements includes a plurality of carrier transport layers and at least one insulating layer, both being layered between the first electrode and the light-emitting layer. The insulating layer is provided at least partially between at least one carrier transport layer among the plurality of carrier transport layers and at least another carrier transport layer overlapping the at least one carrier transport layer.

### TECHNICAL FIELD

The disclosure relates to a light-emitting device including a carrier transport layer and a manufacturing method therefor.

### BACKGROUND ART

PTL 1 to PTL 3, for example, disclose a light-emitting device including a plurality of electron transport layers between an electrode and a light-emitting layer.

According to PTL 1, two or more organic electron transport layers are provided, and a metal phthalocyanine compound is contained in the organic electron transport layer provided in contact with the inorganic electron injection layer, and thereby the organic layer is prevented from being damaged when the cathode is formed by sputtering and the electron injection efficiency is improved.

According to PTL 2, in order to obtain a light-emitting element having a long lifetime and high luminous efficiency, two or more electron transport layers are provided, and the absolute value of the electron affinity of the light-emitting layer is set to be equal to or larger than the absolute value of the electron affinity of the electron transport layer adjacent to the light-emitting layer, and the absolute value of the work function of the cathode is set to be equal to or larger than the absolute value of the electron affinity of the electron transport layer closest to the cathode.

According to PTL 3, by providing, between the light-emitting layer and the cathode, a multi-layered electron transport layer that includes an electron transport layer containing an electron transporting material, and a mixed layer on the light-emitting layer side and a mixed layer on the cathode side containing an organic metal complex compound together with an electron transporting material, the electron injection efficiency is improved and the drive voltage is lowered.

### CITATION LIST

### Patent Literature

PTL 1: JP 2000-340364 A
PTL 2: JP 2016-26416 A
PTL 3: JP 2016-143797 A

### SUMMARY

### Technical Problem

However, when an amount of either electrons or holes become excessive in a light-emitting device, the rate of non-radiative recombination that does not involve light emission in the Auger process or the like increases, and the luminous efficiency of the light-emitting element decreases.

For this reason, in order to improve the luminous efficiency, it is desirable to lower the rate of non-radiative recombination in the light-emitting layer by curbing an excessive amount of carrier current and improving the balance of carriers.

An aspect of the disclosure has been contrived in view of the above problem, and an object of the disclosure is to provide a light-emitting device and a manufacturing method therefor that can improve the balance of carriers compared with the related art.

### Solution to Problem

To solve the above-described problem, a light-emitting device according to an aspect of the disclosure includes at least one light-emitting element including a first electrode and a second electrode facing each other, and a light-emitting layer provided between the first electrode and the second electrode, in which at least one of the light-emitting elements includes a plurality of carrier transport layers and at least one insulating layer, both being layered between the first electrode and the light-emitting layer, and the insulating layer is provided at least partially between at least one carrier transport layer among the plurality of carrier transport layers and at least another carrier transport layer overlapping the at least one carrier transport layer.

To solve the above-described problem, a manufacturing method for a light-emitting device according to an aspect of the disclosure includes forming at least one light-emitting element, in which the forming of the light-emitting element includes forming a lower layer electrode, forming a light-emitting layer, and forming an upper layer electrode, and includes, between the forming of the lower layer electrode and the forming of the light-emitting layer or between the forming of the light-emitting layer and the forming of the upper layer electrode, forming a first carrier transport layer, forming an insulating layer on at least a part of the first carrier transport layer, and forming a second carrier transport layer on the first carrier transport layer with the insulating layer interposed between the first carrier transport layer and the second carrier transport layer.

### Advantageous Effects of Disclosure

According to an aspect of the disclosure, it is possible to provide a light-emitting device and a manufacturing method therefor that can improve the balance of carriers compared with the related art.

### BRIEF DESCRIPTION OF DRAWINGS

FIG. 1 is a cross-sectional view illustrating an example of a schematic configuration of main portions of a light-emitting device according to a first embodiment.

FIG. 2 is a cross-sectional view illustrating an example of a layered structure of a light-emitting element illustrated in FIG. 1.

FIG. 3 is a flowchart showing an example of a manufacturing method for a display device according to the first embodiment.

FIG. 4 is a flowchart showing an example of step S4 shown in FIG. 3.

FIG. 5 is a cross-sectional view illustrating an example of steps S24 to S27 shown in FIG. 4.

FIG. 6 is a cross-sectional view illustrating an example of steps S28 to S31 shown in FIG. 4.

FIG. 7 is a cross-sectional view illustrating an example of steps S32 to S37 shown in FIG. 4.

FIG. 8 is a cross-sectional view illustrating an example of a layered structure of a light-emitting element according to a second embodiment.

FIG. 9 is an energy diagram illustrating a relationship of electron affinities between layers of a light-emitting element according to a third embodiment.

FIG. 10 is a cross-sectional view illustrating an example of a layered structure of a light-emitting element according to a fourth embodiment.

FIG. 11 is a cross-sectional view illustrating an example of a layered structure of a light-emitting element according to a fifth embodiment.

FIG. 12 is a cross-sectional view illustrating an example of a light-emitting element layer in a display device according to a sixth embodiment.

FIG. 13 is a flowchart showing an example of a process for forming a light-emitting element layer according to the sixth embodiment.

FIG. 14 is a cross-sectional view illustrating an example of steps S24 to S42 of FIG. 13.

FIG. 15 is a cross-sectional view illustrating an example of steps S43 to S47 of FIG. 13.

FIG. 16 is a cross-sectional view illustrating an example of steps S48 to S52 of FIG. 13.

FIG. 17 is a cross-sectional view illustrating an example of a layered structure of a light-emitting element according to a seventh embodiment.

FIG. 18 is a cross-sectional view illustrating an example of a layered structure of a light-emitting element according to an eighth embodiment.

### DESCRIPTION OF EMBODIMENTS

Embodiments of the disclosure will be described below. Note that, for convenience of description, members having the same functions as the members described earlier may be denoted by the same reference numerals and signs, and the description thereof will not be repeated. In addition, in the second embodiment and those following, differences from the embodiment described first will be described. Note that it should be obvious that, even in a case where not specified, in the second embodiment and those following, the same modifications as those of the embodiment described first may also be applied. In addition, a description of “from A to B” for two numbers A and B is intended to mean “equal to or greater than A and equal to or less than B” unless otherwise specified.

### First Embodiment

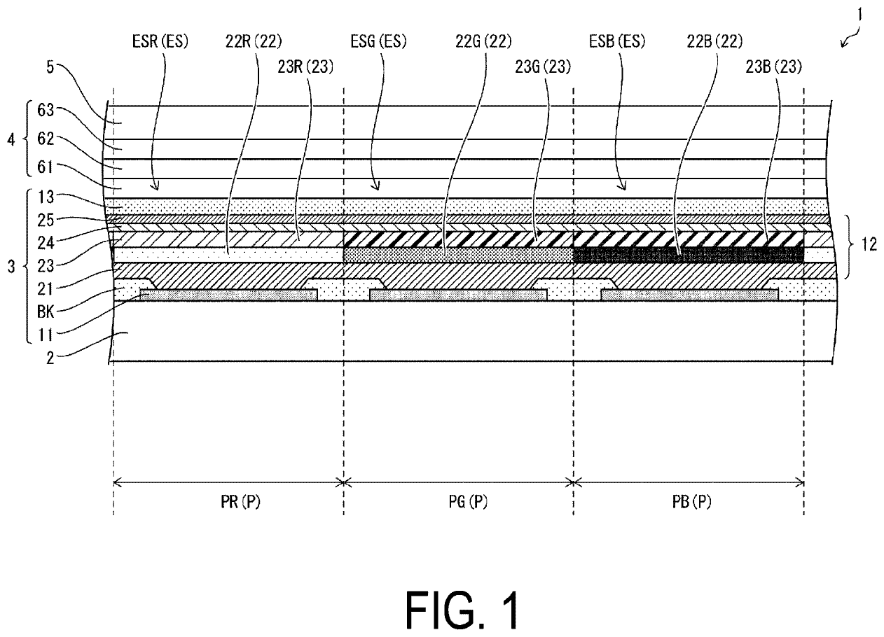

An embodiment of the disclosure will be described as follows with reference to FIG. 1 to FIG. 7. Note that, in the following, description is made using, as an example, a case in which a light-emitting device according to the present embodiment is a display device.

Schematic Configuration of Display Device FIG. 1 is a cross-sectional view illustrating an example of a schematic configuration of main portions of a display device 1 (light-emitting device) according to the present embodiment.

The display device 1 includes a plurality of pixels P. A light-emitting element ES is provided in each pixel P. The display device 1 illustrated in FIG. 1 includes, as a substrate 2, an array substrate formed with a drive element layer, and has a configuration in which a light-emitting element layer 3 including a plurality of light-emitting elements ES having different light emission wavelengths, a sealing layer 4, and a function film 5 are layered in this order on the substrate 2. Note that, in the present embodiment, a direction from the light-emitting elements ES of the display device 1 to the substrate 2 is referred to as a “downward direction”, and a direction from the substrate 2 of the display device 1 to the light-emitting elements ES is referred to as an “upward direction”. In addition, in the present embodiment, a “lower layer” refers to a layer that is formed in a process prior to that of a layer to be compared, and an “upper layer” refers to a layer that is formed in a process after that of a layer to be compared.

The display device 1 illustrated in FIG. 1 includes, as pixels P, a red pixel PR that emits red light, a green pixel PG that emits green light, and a blue pixel PB that emits blue light. A bank BK having insulating properties is provided between the pixels P, for example, the bank functioning as an edge cover that covers the edges of lower layer electrodes (the anodes 11 in the example illustrated in FIG. 1) and functioning as a pixel separation film that partitions adjacent pixels.

The display device 1 includes a plurality of light-emitting elements ES having different light emission wavelengths. The display device 1 includes, as the plurality of light-emitting elements ES, a red light-emitting element ESR (first light-emitting element), a blue light-emitting element ESB (second light-emitting element), and a green light-emitting element ESG (third light-emitting element). The red light-emitting element ESR emits red light (light of a first color). The blue light-emitting element ESB emits blue light (light of a second color). The green light-emitting element ESG emits green light (light of a third color).

In the red pixel PR (first pixel), the red light-emitting element ESR is provided as a light-emitting element ES. In the blue pixel PB (second pixel), the blue light-emitting element ESB is provided as a light-emitting element ES. In the green pixel PG (third pixel), the green light-emitting element ESG is provided as a light-emitting element ES.

In the disclosure, in a case that there is no particular need to distinguish between the red light-emitting element ESR, the green light-emitting element ESG, and the blue light-emitting element ESB, the red light-emitting element ESR, the green light-emitting element ESG, and the blue light-emitting element ESB are collectively referred to simply as “light-emitting elements ES”. Likewise, in the disclosure, in a case that there is no particular need to distinguish between the red pixel PR, the green pixel PG, and the blue pixel PB, the red pixel PR, the green pixel PG, and the blue pixel PB are collectively referred to simply as “pixels P”.

The light-emitting element layer 3 includes the plurality of light-emitting elements ES respectively provided for each pixel P, and has a structure in which each layer of the light-emitting elements ES is layered over the substrate 2.

The substrate 2 functions as a support body for forming each layer of the light-emitting elements ES. The substrate 2 is an array substrate. The substrate 2 has, for example, a configuration in which a thin film transistor layer (TFT layer) having a plurality of thin film transistors (TFTs) is provided on an insulating substrate as a base substrate.

The insulating substrate may be, for example, an inorganic substrate made of an inorganic material such as glass, quartz, or ceramics, or a flexible substrate made primarily of a resin such as polyethylene terephthalate or polyimide. In a case where the insulating substrate is a flexible substrate, the insulating substrate may be formed of a resin film (resin layer) such as a polyimide film, or may be composed of two resin films and an inorganic insulating film interposed between these resin films.

Furthermore, a barrier layer may be provided on a surface of the insulating substrate to prevent foreign matter such as water and oxygen from entering the TFT layer and the light-emitting element layer 3. Such a barrier layer can be composed of, for example, a silicon oxide film, a silicon nitride film, or a silicon oxynitride film formed by chemical vapor deposition (CVD), or of a layered film of these films.

Pixel circuits that control each light-emitting element ES and a plurality of wiring lines connected to the pixel circuits are formed in the TFT layer. The pixel circuits are provided for each pixel P to correspond to the pixel P in a display region. The pixel circuits include a plurality of TFTs. The plurality of TFTs are electrically connected to a plurality of wiring lines including wiring lines such as gate wiring lines and source wiring lines. For these TFTs, a known structure can be employed, and the structure is not particularly limited.

A flattening film covering the plurality of TFTs is provided on the surface of the TFT layer so that the surfaces of the plurality of TFTs are planarized. The flattening film can be composed of, for example, an organic insulating material such as a polyimide resin or an acrylic resin.

The light-emitting element layer 3 includes a plurality of anodes 11 provided on the flattening film, a cathode 13, a function layer 12 provided between the anodes 11 and the cathode 13, and the banks BK having insulating properties and covering the edge of each of the anodes 11. In the present embodiment, the layers between the anodes 11 and the cathode 13 facing each other are collectively referred to as the “function layer 12”.

Note that FIG. 1 illustrates an example in which the anodes 11 are lower layer electrodes and the cathode 13 is an upper layer electrode provided above the lower layer electrodes via the function layer 12 and the banks BK. Hereinafter, the case in which the anodes 11 are lower layer electrodes and the cathode 13 is an upper layer electrode as illustrated in FIG. 1 will be described as an example. However, the display device 1 is not limited to this, and the cathode 13 may be a lower layer electrode and the anodes 11 may be upper layer electrodes.

The anodes 11 serving as lower layer electrodes function as so-called pixel electrodes (island-shaped lower layer electrodes) and are provided on the substrate 2 in an island shape for each light-emitting element ES (in other words, for each pixel). The cathode 13 which is an upper layer electrode is provided as a common electrode (common upper electrode) in common to all the light-emitting elements ES (in other words, all the pixels). The light-emitting elements ES function as light sources that light up each of the pixels.

The banks BK are used as edge covers that cover the edges of the patterned lower layer electrodes and also function as pixel separation films. An insulating organic material can be used for the banks BK. The insulating organic material preferably contains a photosensitive resin. For example, a polyimide resin, an acrylic resin, and the like can be used as the insulating organic material. The banks BK are formed in a lattice pattern, for example, in a plan view to surround each of the pixels P.

Each of the light-emitting elements ES including the anode 11, the function layer 12, and the cathode 13 is provided corresponding to one pixel P in the light-emitting element layer 3. Each anode 11 serving as the lower layer electrode is electrically connected to the TFT of the substrate 2.

The function layer 12 includes at least a light-emitting layer, a plurality of carrier transport layers layered between at least one electrode (first electrode) of the anode 11 and the cathode 13 and the light-emitting layer, and at least one insulating layer. The first electrode may be the cathode 13 or may be the anode 11. Thus, the function layer 12 may include a plurality of electron transport layers as the plurality of carrier transport layers between the cathode 13 and the light-emitting layer, and may include a plurality of hole transport layers as the plurality of carrier transport layers between the anode 11 and the light-emitting layer. Of course, a plurality of electron transport layers may be provided between the cathode 13 and the light-emitting layer, and a plurality of hole transport layers may be provided between the anode 11 and the light-emitting layer.

The insulating layer is provided at least partially between at least one carrier transport layer among the plurality of carrier transport layers and at least another carrier transport layer overlapping the at least one carrier transport layer.

Hereinafter, an electron transport layer will be referred to as “ETL”, and a hole transport layer will be referred to as “HTL”. Furthermore, the light-emitting layer will be referred to as “EML”, and the insulating layer will be referred to as “IL”. In addition, an electrode of the anodes 11 and the cathode 13 which is different from the first electrode is referred to as a second electrode.

In the present embodiment, as an example, a case in which the first electrode is the cathode 13, the function layer 12 includes a plurality of ETLs as the plurality of carrier transport layers between the cathode 13 and the EML, and the IL is provided between the ETLs will be described.

The red light-emitting element ESR illustrated in FIG. 1 has a configuration in which an anode 11 (second electrode), an HTL 21, an EML 22R, an ETL 23R (first ETL or first carrier transport layer), an IL 24, an ETL 25 (second ETL or second carrier transport layer), and a cathode 13 (first electrode) are layered in this order from the substrate 2 side. In addition, the green light-emitting element ESG illustrated in FIG. 1 has a configuration in which an anode 11, an HTL 21, an EML 22G, an ETL 23G (first ETL or first carrier transport layer), an IL 24, an ETL 25 (second ETL or second carrier transport layer), and a cathode 13 are layered in this order from the substrate 2 side. The blue light-emitting element ESB illustrated in FIG. 1 has a configuration in which an anode 11, an HTL 21, an EML 22B, an ETL 23B (first ETL or first carrier transport layer), an IL 24, an ETL 25 (second ETL or second carrier transport layer), and a cathode 13 are layered in this order from the substrate 2 side. In the present embodiment, the plurality of ETLs layered in each of the light-emitting elements ES are referred to as a first ETL and a second ETL in order from the lower layer side for convenience of description.

The EML 22R is a red EML that emits red light, and is formed in an island shape in the red pixel PR. The EML 22B is a blue EML that emits blue light and is formed in an island shape in the blue pixel PB. The EML 22G is a green EML that emits green light and is formed in an island shape in the green pixel PG. The EML 22R, the EML 22G, and the EML 22B may be in contact with each other as illustrated in FIG. 1 or may be separated from each other.

In addition, in the present embodiment, the ETL 23R, the ETL 23G, and the ETL 23B, which are the first ETL in each of the light-emitting elements ES, are island-shaped individual ETLs (individual carrier transport layers) provided for each of the light-emitting elements ES. The ETL 23R is formed in an island shape in the red pixel PR. The ETL 23B is formed in an island shape in the blue pixel PB. The ETL 23G is formed in an island shape in the green pixel PG. The ETL 23R, the ETL 23G, and the ETL 23B may also be in contact with each other as illustrated in FIG. 1, or may be separated from each other.

In a case where there is no particular need to distinguish between the EML 22R, the EML 22G, and the EML 22B in the disclosure, the EML 22R, the EML 22G, and the EML 22B are collectively referred to simply as “EMLs 22”. Likewise, in a case where there is no particular need to distinguish between the ETL 23R, the ETL 23G, and the ETL 23B in the disclosure, the ETL 23R, the ETL 23G, and the ETL 23B are collectively referred to simply as “ETLs 23” or the “first ETL”.

On the other hand, in the present embodiment, the HTL 21 and the ETL 25 (second ETL) are common carrier transport layers provided in common to all the light-emitting elements ES. In addition, the HTL 21 is a common insulating layer provided in common to all the light-emitting elements ES.

Note that a configuration of each of the layers of the light-emitting element ES will be described in more detail below.

The light-emitting element layer 3 is covered by the sealing layer 4. The sealing layer 4 has light-transmitting properties and includes, for example, a first inorganic sealing film 61, an organic sealing film 62, and a second inorganic sealing film 63 in order from the lower layer side (that is, the light-emitting element layer 3 side). However, the sealing layer 4 is not limited thereto, and the sealing layer may be formed of a single layer of an inorganic sealing film or a layered body of five or more layers including organic sealing films and inorganic sealing films. In addition, the sealing layer 4 may be sealing glass, for example. The light-emitting elements ES are sealed by the sealing layer 4, and thus water, oxygen, or the like can be prevented from permeating into the light-emitting elements ES.

Each of the first inorganic sealing film 61 and the second inorganic sealing film 63 can be formed of, for example, a silicon oxide film, a silicon nitride film, or a silicon oxynitride film formed by chemical vapor deposition (CVD), or of a layered film of these films. The organic sealing film 62 is a light-transmissive organic film thicker than the first inorganic sealing film 61 and the second inorganic sealing film 63, and can be formed of, for example, a coatable photosensitive resin such as a polyimide resin or an acrylic resin.

Note that, as illustrated in FIG. 1, the display device 1 may include, on the sealing layer 4, the function film 5 having at least one of an optical compensation function, a touch sensor function, and a protection function, for example.

### Schematic Configuration of Light-Emitting Element ES

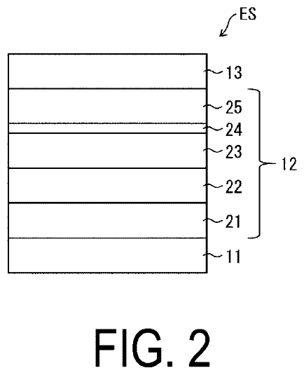

FIG. 2 is a cross-sectional view illustrating an example of a layered structure of the light-emitting elements ES illustrated in FIG. 1.

Each light-emitting element ES according to the present embodiment has a configuration in which the anode 11, the HTL 21, the EML 22, the ETL 23 (first ETL), the IL 24, the ETL 25 (second ETL), and the cathode 13 are adjacent to each other and layered in this order from the lower layer side as illustrated in FIG. 1 and FIG. 2. The light-emitting element ES includes the HTL 21, the EML 22, the ETL 23, the IL 24, and the ETL 25 as the function layer 12.

The anode 11 and the cathode 13 are connected to a power supply, which is not illustrated, (for example, a DC power supply), and thus a voltage is applied therebetween. The anode 11 and the cathode 13 include a conductive material, and are electrically connected to the HTL 21 and the ETL 25, respectively.

The anode 11 (second electrode) is an electrode that supplies positive holes (holes) to the EML 22 when a voltage is applied thereto. The cathode 13 (first electrode) is an electrode that supplies electrons to the EML 22 when a voltage is applied thereto.

At least one of the anode 11 and the cathode 13 is a light-transmissive electrode. Note that either the anode 11 or the cathode 13 may be a so-called reflective electrode having light reflectivity. The light-emitting element ES can take light from the light-transmissive electrode side.

For example, in a case where the light-emitting element ES is a top-emission type light-emitting element that emits light from the upper layer electrode side, a light-transmissive electrode is used as the upper layer electrode, and a reflective electrode is used as the lower layer electrode. On the other hand, in a case where the light-emitting element ES is a bottom-emission type light-emitting element that emits light from the lower layer electrode side, a light-transmissive electrode is used as the lower layer electrode, and a reflective electrode is used as the upper layer electrode.

The light-transmissive electrode is formed of a conductive light-transmissive material, for example, indium tin oxide (ITO), indium zinc oxide (IZO), silver nanowire (AgNW), a thin film of a magnesium-silver (MgAg) alloy, a thin film of silver (Ag), or the like.

On the other hand, the reflective electrode is formed of a conductive light-reflective material, for example, a metal such as silver (Ag), aluminum (Al), or copper (Cu), or an alloy including these metals. Note that the reflective electrode may be obtained by layering a layer made of the light-transmissive material and a layer made of the light-reflective material.

The HTL 21 is a layer that contains a hole transporting material and transports holes supplied from the anode 11 to the EML 22. The hole transporting material may be an organic material or may be an inorganic material.

In a case where the hole transporting material is an organic material, examples of the organic material include conductive polymer materials, for example, poly [(9,9-dioctylfluorenyl-2,7-diyl)-co-(4,4′-(N-(4-sec-butylphenyl)diphenylamine))] (TFB), poly(3,4-ethylenedioxythiophene)-poly(styrenesulfonate)(PEDOT:PSS), and poly(N-vinylcarbazole)(PVK). In addition, in a case where the hole transporting material is an inorganic material, examples of the inorganic material include NiO, MoO₃, MgO, MgNiO, and LaNiO₃. A single type of these hole transporting materials may be used alone, or two or more types thereof may be mixed and used, as appropriate.

The EML 22 contains a light-emitting material and emits light through recombination of holes transported from the anode 11 and electrons transported from the cathode 13. The light-emitting element ES according to the present embodiment is a quantum dot light-emitting diode (QLED), and the EML 22 contains nano-sized quantum dots (hereinafter, referred to as “QDs”) corresponding to a light emission color as a light-emitting material.

QDs are dots including inorganic nanoparticles with a maximum width of 100 nm or less. QDs generally have a composition derived from a semiconductor material, and thus may also be called semiconductor nanoparticles. Furthermore, since QDs have a specific crystal structure, for example, they may also be called nanocrystals.

The shape of the QDs is not particularly limited as long as it is within a range satisfying the maximum width, and the shape thereof is not limited to a spherical three-dimensional shape (circular cross-sectional shape). The shape may be, for example, a polygonal cross-sectional shape, a rod-shaped three-dimensional shape, a branch-shaped three-dimensional shape, or a three-dimensional shape having unevenness on the surface thereof, or a combination thereof.

The QDs may be of a core type, a core-shell type including a core and a shell, or a core-multi-shell type. Furthermore, the QDs may be of a two-component core type, a three-component core type, or a four-component core type. Note that the QDs may include doped nanoparticles, or may have a compositionally graded structure.

The core may be formed of, for example, Si, Ge, CdSe, CdS, CdTe, InP, GaP, InN, ZnSe, ZnS, ZnTe, CdSeTe, GaInP, ZnSeTe, or the like. The shell may be formed of, for example, CdS, ZnS, CdSSe, CdTeSe, CdSTe, ZnSSe, ZnSTe, ZnTeSe, AIP, or the like.

The QDs can have light emission wavelengths changed variously depending on, for example, particle sizes and compositions thereof. The QDs are QDs that emit visible light, and the light emission wavelength can be controlled from the blue wavelength range to the red wavelength range by appropriately adjusting the particle size and composition of the QDs.

Thus, the QDs may be, for example, blue QDs that emit blue light, green QDs that emit green light, or red QDs that emit red light.

The EML 22R contains red QDs as QDs. The EML 22G contains green QDs as QDs. The EML 22B contains blue QDs as the QDs. The same light-emitting elements ES (the same pixels P) have the same type of QDs.

Here, the blue light refers to, for example, light having an emission peak wavelength in a wavelength band of 400 nm or greater and 500 nm or less. In addition, the green light refers to, for example, light having an emission peak wavelength in a wavelength band over 500 nm and 600 nm or less. In addition, the red light refers to light having an emission peak wavelength in a wavelength band exceeding 600 nm and 780 nm or less.

As described above, the EML 22 according to the present embodiment is a QD light-emitting layer containing the QDs. In the light-emitting element ES according to the present embodiment, electrons and holes recombine inside the EML 22 in response to a drive current applied between the anode 11 and the cathode 13, which generates excitons to emit light in the process of transition from a conduction band level to a valence band level of the QDs.

The ETL 23 and the ETL 25 are layers having electron transportability that transport (inject) electrons supplied from the cathode 13 to the EML 22. In the present embodiment, the ETL 25 (second ETL) transports electrons supplied from the cathode 13 to the ETL 23 (first ETL), and the ETL 23 transports electrons transported from the ETL 25 to the EML 22.

As the material of the ETL 23 and the ETL 25, for example, an electron transporting material such as ZnO, MgZnO, TiO₂, Ta₂O₃, SrTiO₃, ZrO₂, or Ta₂O₅ is used. As the electron transporting material, an inorganic material is often used as described above. However, the electron transporting material is not limited thereto, and may be an organic material. In a case where the electron transporting material is an organic material, examples of the organic material include 1,3,5-tris(1-phenyl-1H-benzimidazol-2-yl)benzene (TPBi), 3-(biphenyl-4-yl)-4-phenyl-5-(4-tert-butylphenyl)-4-phenyl-4H-1,2,4-triazole (TAZ), bathophenanthroline (Bphen), and tris(2,4,6-trimethyl-3-(pyridin-3-yl)phenyl) borane (3TPYMB). Only one type of these electron transporting materials may be used, or two or more types thereof may be mixed and used as appropriate.

The IL 24 having light-transmitting properties is provided between the ETL 23 and the ETL 25, in contact with the ETL 23 and the ETL 25. In other words, the IL 24 is sandwiched between the ETL 23 and the ETL 25. The IL 24 according to the present embodiment is formed in a thin film shape in an entire region between the ETL 23 and the ETL 25. Note that a layer thickness of the IL 24 is preferably 20 nm or less, and more preferably 10 nm or less.

When an amount of either electrons or holes become excessive in a light-emitting device such as a display device as described above, the rate of non-radiative recombination that does not involve light emission in the Auger process or the like increases, and the luminous efficiency of the light-emitting element decreases.

For this reason, in order to improve the luminous efficiency, it is desirable to lower the rate of non-radiative recombination in the EML by curbing an excessive amount of carrier current and improving the balance of carriers.

An electroluminescent element tends to have a low carrier mobility in the HTL as compared with in the ETL in most cases. Thus, the amount of electron injected is greater than the amount of hole injected in the EML, thereby typically raising a problem of excessive electron supply and hole shortage. When the amount of electrons is excessive, the probability of occurrence of electron-hole recombination that does not involve light emission in an Auger process in addition to electron-hole recombination to be taken as light increases, and the luminous efficiency of the electroluminescent element is lowered. Furthermore, the overflowing electrons induce an electrochemical reaction in the HTL, which reduces the reliability of the electroluminescent element and the reliability of the light-emitting device including the electroluminescent element.

According to the present embodiment, since the ETL 23 and the ETL 25 are provided with the IL 24 interposed therebetween, it is possible to reduce the amount of electrons injected between the ETL 23 and the ETL 25, suppress an excessive amount of electrons from being injected from the cathode 13 to the EML 22, and improve the balance of carriers. As a result, the rate of non-radiative recombination in the EML 22 can be lowered, and the improvement in luminous efficiency can be realized. Thus, according to the present embodiment, it is possible to provide, for example, the display device 1 with higher luminous efficiency and reliability as a light-emitting device.

In addition, as described above, since the side IL 24 is formed in a thin film shape in the entire region between the ETL 23 and the ETL 25 overlapping the ETL 23, it is possible to suppress local current concentration and to further improve the reliability of the display device 1.

The IL 24 may have a light-transmitting property, but is preferably transparent. Various known insulating materials having light-transmitting properties can be used as materials of the IL 24. Examples of the above-described insulating material include inorganic insulating materials such as silicon oxide (SiO₂), silicon nitride (SiN), and silicon oxynitride (SiON) and organic insulating materials such as epoxy resins, acrylic resins, polyimide resins, silicone resins, and fluorine compounds. One type of these insulating materials may be used alone, or two or more types thereof may be mixed and used as appropriate.

Since the IL 24 contains a photosensitive insulating material having photosensitivity, for example, epoxy resins, acrylic resins, polyimide resins, water-soluble resins, styrene resins, and the like, the IL 24 can be easily patterned, and control of a carrier injection path and adjustment of mobility of carriers can be easily performed.

In addition, it is preferable that at least a part of the IL 24 contains a liquid-repellent material having liquid repellency against organic solvents. The IL 24 may be formed of, for example, a liquid-repellent material having liquid repellency against organic solvents, or a surface thereof may be subjected to a liquid-repellent treatment with such a liquid-repellent material. In other words, the IL 24 may have surfaces subjected to a liquid-repellent treatment.

This makes it possible to prevent the organic solvents contained in the coating liquid of the ETL 25 from permeating into the ETL 23 and further into a layer (for example, the EML 22) on the lower layer side of the ETL 23 through the ETL 23 during the formation of the ETL 25. Therefore, for example, it is possible to prevent the ETL 23 and further a layer on the lower layer side of the ETL 23, for example, the EML 22 from being damaged by the organic solvents contained in the coating liquid of the ETL 25.

In addition, according to the above-described configuration, in a case where polar solvents are used for the coating liquid of the ETL 23 and the coating liquid of the ETL 25, it is possible to prevent the material of the ETL 23 from being dissolved or dispersed in the organic solvents contained in the coating liquid of the ETL 25 when the ETL 25 is formed. For this reason, even if the solvents contained in the coating liquid of the ETL 23 and the coating liquid of the ETL 25 have the same polarity as described above, it is possible to avoid damage that the shape of the ETL 23 on the lower layer side cannot be maintained.

The liquid-repellent material is not particularly limited, but is preferably at least one type selected from the group consisting of fluorine compounds, silicone resins, and acrylic resins. These liquid-repellent materials have high liquid repellency with respect to an organic solvent used in a coating liquid of a carrier transporting material (in the present embodiment, a coating liquid of the electron transporting material) and an organic solvent used in a coating liquid of a photosensitive resist material for forming a lift-off template to be described later. For this reason, it is possible to suppress or prevent the permeation of solvents of the IL 24 into the lower layer during the film formation of the ETL 25 on the upper layer side of the IL 24, and to protect the layers such as the ETL 23 and the EML 22 positioned on the lower layer side of the IL 24. Therefore, these liquid-repellent materials can be suitably used as a liquid-repellent material.

In addition, among these liquid-repellent materials, a fluorine compound can be more suitably used as a liquid-repellent material because the fluorine compound has particularly high liquid repellency against the organic solvent used in the coating liquid of the carrier-transporting material (in the case of the present embodiment, the coating liquid of the electron transporting material). Therefore, the liquid-repellent material more preferably contains a fluorine compound.

Examples of the fluorine compound include 1H, 1H,2H,2H-perfluoro-n-hexylphosphonic acid (FHPA), 1H, 1H,2H,2H-perfluoro-n-octylphosphonic acid (FOPA), 1H, 1H,2H,2H-perfluoro-n-decylphosphonic acid (FDPA), and the like. In addition, the fluorine compound may be, for example, a compound containing a fluoroalkyl group.

The IL 24 may be thick enough to allow carriers to move by tunnel conduction. Therefore, the IL 24 preferably has a thickness equal to or less than 5 nm (that is, more than 0 and equal to or less than 5 nm), more preferably has a thickness equal to or less than 1.5 nm. As an example, the IL 24 may be a self-assembled monolayer of a fluorine compound.

### Manufacturing Method for Display Device 1

Next, a manufacturing method for the display device 1 described above will be described.

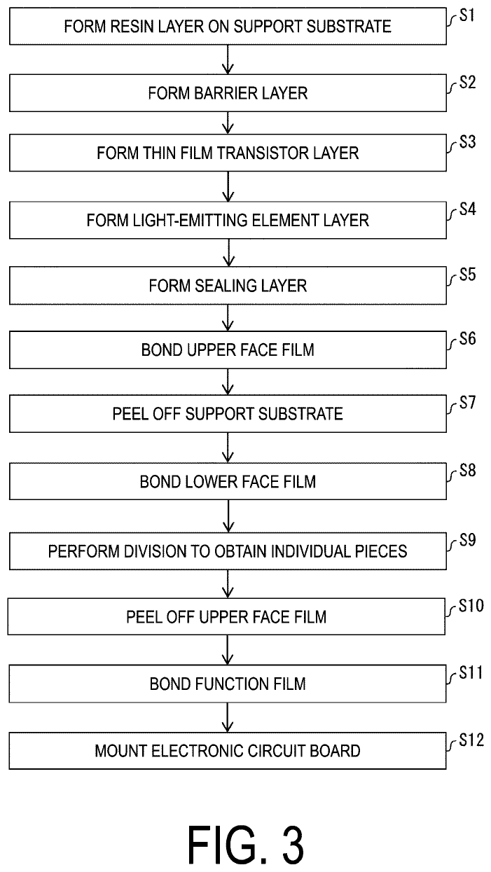

FIG. 3 is a flowchart showing an example of a manufacturing method for the display device 1 according to the present embodiment.

In a case where a flexible display device is manufactured as the display device 1, as illustrated in FIG. 3 (step S1), first, a resin layer that will serve as an insulating substrate for the substrate 2 is formed on a light-transmissive support substrate (for example, mother glass), which is not illustrated. Next, a barrier layer is formed (step S2). Next, a thin film transistor layer (TFT layer) is formed (step S3). Next, the light-emitting element layer 3 is formed (step S4; light-emitting element forming step). Next, the sealing layer 4 is formed (step S5). Next, an upper face film for protection, which is not illustrated, is temporarily bonded onto the sealing layer 4 (step S6). Next, the support substrate is peeled from the resin layer through irradiation with laser light or the like (step S7). Next, a lower face film, which is not illustrated, is bonded to the lower face of the resin layer (step S8). Next, a layered body including the lower face film, the resin layer, the barrier layer, the TFT layer, the light-emitting element layer 3, the sealing layer 4, and the upper face film is divided to obtain a plurality of individual pieces (step S9). Next, the upper face film is peeled from the obtained individual pieces (step S10), and then the function film 5 is bonded (step S11). Next, an electronic circuit board (for example, an IC chip, an FPC, or the like), which is not illustrated, is mounted on a portion (a terminal portion) of the outer side (frame region) of the display region in which a plurality of pixels P are formed (pixel region)(step S12). Note that steps S1 to S12 are performed by a manufacturing apparatus of the display device 1 (including a film formation apparatus that performs each step of steps S1 to S5).

The upper face film is bonded onto the sealing layer 4 as described above and functions as a support material when the support substrate is peeled off. Examples of the upper face film include a polyethylene terephthalate (PET) film and the like. The lower face film is, for example, a PET film for achieving the display device 1 having excellent flexibility by being bonded to the lower face of the resin layer after the support substrate is peeled off. Note that the resin layer and the barrier layer are as described above.

Note that, although the manufacturing method for the display device 1 having flexibility has been described above, normally, processes such as formation of the resin layer and replacement of a base material are not required for producing the display device 1 having no flexibility. For this reason, for example, in a case where the display device 1 having no flexibility is to be manufactured, the layering step of steps S2 to S5 is performed on a glass substrate, after which the process proceeds to step S9.

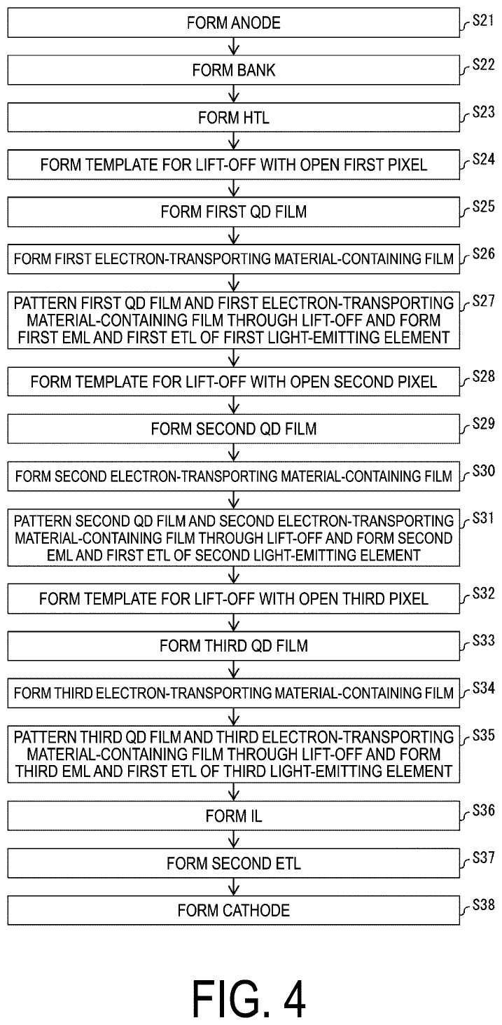

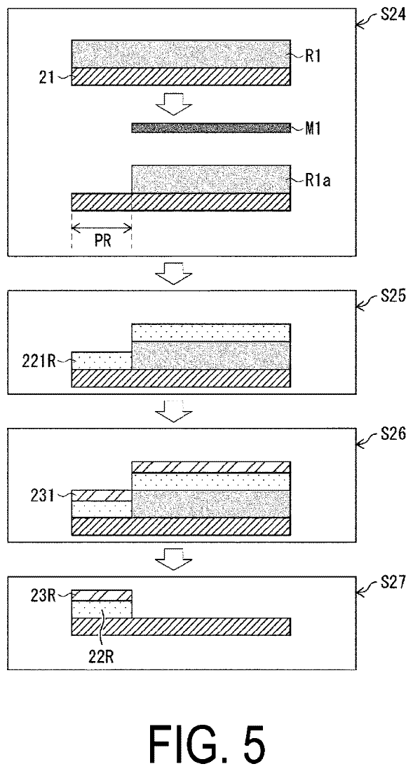

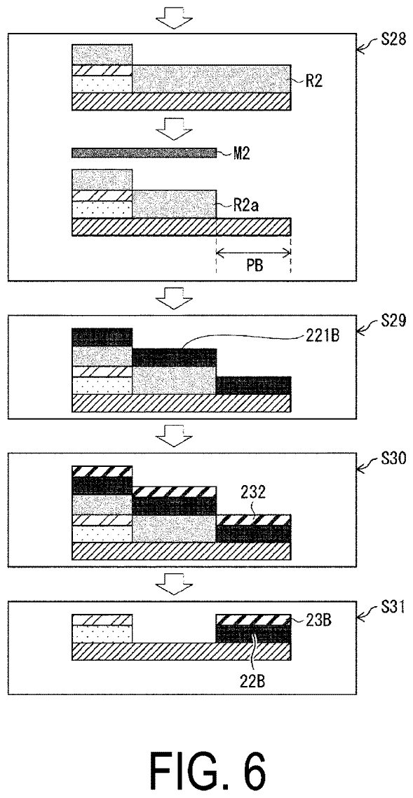

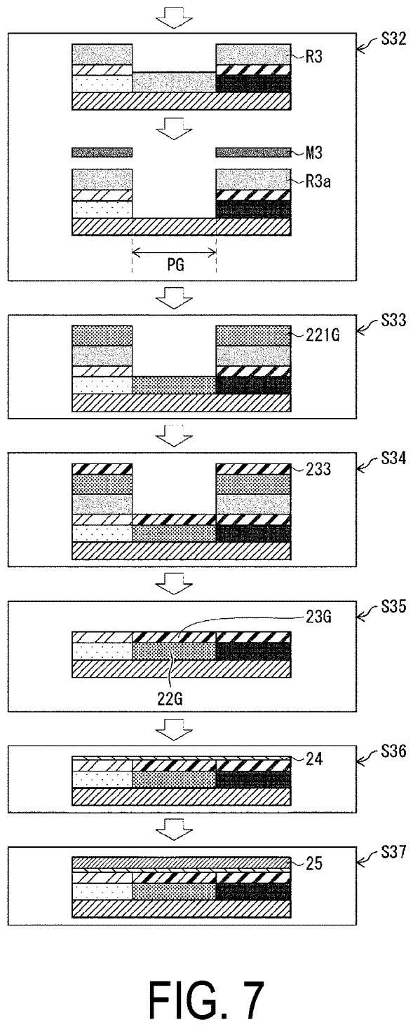

FIG. 4 is a flowchart showing an example of a step of forming the light-emitting element layer 3 indicated in step S4 shown in FIG. 3. FIG. 5 is a cross-sectional view illustrating an example of steps S24 to S27 shown in FIG. 4. FIG. 6 is a cross-sectional view illustrating an example of steps S28 to S31 shown in FIG. 4. FIG. 7 is a cross-sectional view illustrating an example of steps S32 to S37 shown in FIG. 4.

A case in which the light-emitting element ES has the configuration illustrated in FIGS. 1 and 2 will be described as an example in FIGS. 4 to 7. In addition, in FIGS. 4 to 7, a case where the EML 22R, the EML 22B, and the EML 22G, and the ETL 23R, the ETL 23B, and the ETL 23G are formed in the order of the red pixel PR, the blue pixel PB, and the green pixel PG will be described as an example. However, a formation order of the EML 22R, the EML 22G, and the EML 22B, and the ETL 23R, the ETL 23G, and the ETL 23B is not limited to the above order.

In the step of forming the light-emitting element layer 3 (step S4), the anode 11 is first formed on the substrate 2 (to be specific, on the TFT layer formed in step S3) as shown in FIG. 4 (step S21). Step S21 is a step of forming the lower layer electrode. A vapor deposition method, a sputtering method, or the like, for example, is used for forming the anode 11 (film formation). The anode 11 is a pixel electrode formed in an island shape for each pixel P as described above, and is patterned for each pixel P. At this time, the anode 11 may be formed by, for example, forming a film with a conductive material in a solid state over the entire pixel region (display region) and then patterning the film for each pixel P by using a photolithography method or the like.

Next, a bank BK is formed to cover an edge of the anode 11 (step S22). The bank BK can be formed in a desired shape by, for example, applying an insulating organic material such as a photosensitive resin to the entire pixel region in a solid state by using a sputtering method, a vapor deposition method, or the like, and then patterning the insulating organic material in the photolithography method or the like.

Next, the HTL 21 is formed (step S23). For the formation of the HTL 21, for example, a coating method, a sputtering method, a sol-gel method, or the like is used. In FIG. 1, a solid HTL is formed over the entire pixel region as the HTL 21.

Next, a template R1a for lift-off with an opening in the region corresponding to the red pixel PR (first pixel) is formed through photolithography (step S24) as shown in FIGS. 4 and 5. To be specific, first, a photoresist R1 for a template is formed in a solid state over the entire pixel region on the HTL 21 serving as a base layer. Next, by using a mask M1 with an opening in the region corresponding to the red pixel PR, exposure is performed with ultraviolet rays (UV), and then development is performed with a developer. As a result, the template R1a is formed.

Next, on the HTL 21 on which the template R1a is formed, a QD film 221R containing red QDs is formed as a red QD film (first QD film) in a solid state over the entire pixel region (step S25). Step S25 is a step of forming a light-emitting layer in the red light-emitting element ESR. In step S25, a red QD dispersion liquid containing red QDs and solvents is applied in a solid state onto the HTL 21 on which the template R1a is formed, and the solvents are removed. Thus, a solid QD film HTL 221R covering the template R1a is formed on the HTL 21.

Next, an electron-transporting material-containing film 231 (first electron-transporting material-containing film) containing an electron transporting material is formed in a solid state on the QD film 221R (step S26). Step S26 is a step of forming a first carrier transport layer in the red light-emitting element ESR. The electron-transporting material-containing film 231 can be formed by applying an electron-transporting material-containing liquid (first electron-transporting material-containing liquid) containing an electron transporting material (first electron transporting material) and a solvent onto the QD film 221R in a solid state and removing the solvent.

Next, the template R1a is removed with an organic solvent to lift off the QD film 221R and the electron-transporting material-containing film 231 formed on the template R1a. Thus, the QD film 221R and the electron-transporting material-containing film 231 are patterned to form, as a red EML (first EML), the EML 22R made of the QD film 221R on the HTL 21 of the red pixel PR, and to form the ETL 23R made of the electron-transporting material-containing film 231 as a first ETL of the red light-emitting element (first light-emitting element)(step S27).

Next, by repeating steps similar to steps S24 to S27 for the blue pixel PB and the green pixel PG, the EML 22B and the ETL 23B are formed in the blue pixel PB, and the EML 22G and the ETL 23G are formed in the green pixel PG.

Specifically, after step S27, a template R1a for lift-off with an opening of the blue pixel PB (second pixel) is formed through photolithography (step S28) as shown in FIGS. 4 and 6. To be specific, first, a photoresist R2 for a template is formed in a solid state over the entire pixel region to cover the ETL 23R on the HTL 21 serving as a base layer. Next, by using a mask M2 in which the region corresponding to the blue pixel PB is opened, exposure is performed with UV, and then development is performed with a developer. As a result, the template R2a is formed.

Next, on the HTL 21 on which the template R2a and the ETL 23R are formed, a QD film 221B containing blue QDs is formed as a blue QD film (second QD film) in a solid state over the entire pixel region (step S29). In step S29, a blue QD dispersion liquid containing blue QDs and solvents is applied in a solid state onto the HTL 21 on which the template R2a and the ETL 23R are formed, and the solvents are removed. Thus, a solid QD film HTL 221B covering the template R2a and the ETL 23R is formed on the HTL 21.

Next, an electron-transporting material-containing film 232 (second electron-transporting material-containing film) containing an electron transporting material to form the ETL 23B is formed in a solid state on the QD film 221B (step S30). The electron-transporting material-containing film 232 can be formed by applying a second electron-transporting material-containing liquid containing an electron transporting material for the ETL 23B and solvents onto the QD film 221B in a solid state and removing the solvents.

Next, the template R2a is removed with an organic solvent to lift off the QD film 221B and the electron-transporting material-containing film 232 formed on the template R2a. Thus, the QD film 221B and the electron-transporting material-containing film 232 are patterned to form, as a blue EML (second EML), the EML 22B made of the QD film 221B on the HTL 21 of the blue pixel PB, and to form the ETL 23B made of the electron-transporting material-containing film 232 as a first ETL of the blue light-emitting element (second light-emitting element)(step S31).

Next, as shown in FIGS. 4 and 7, a template R3a for lift-off with an opening in the region corresponding to the green pixel PG (third pixel) is formed through photolithography (step S32). To be specific, first, a photoresist R3 for a template is formed in a solid state over the entire pixel region to cover the ETL 23R and the ETL 23B on the HTL 21 serving as a base layer. Next, by using a mask M3 with an opening in the region corresponding to the green pixel PG, exposure is performed with UV, and then development is performed with a developer. As a result, the template R3a is formed.

Next, on the HTL 21 on which the template R3a, the ETL 23R, and the ETL 23B are formed, a QD film 221G containing green QDs is formed as a green QD film (third QD film) in a solid state over the entire pixel region (step S33). In step S33, a green QD dispersion liquid containing green QDs and solvents is applied in a solid state onto the HTL 21 on which the template R3a, the ETL 23R, and the ETL 23B are formed, and the solvents are removed. Thus, a solid QD film HTL 221G covering the template R3a, the ETL 23R, and the ETL 23B is formed on the HTL 21.

Next, an electron-transporting material-containing film 233 (third electron-transporting material-containing film) containing an electron transporting material to form the ETL 23G is formed in a solid state on the QD film 221G (step S34). The electron-transporting material-containing film 233 can be formed by applying a second electron-transporting material-containing liquid containing an electron transporting material for the ETL 23G and solvents onto the QD film 221G in a solid state and removing the solvents.

Next, the template R3a is removed with an organic solvent to lift off the QD film 221G and the electron-transporting material-containing film 233 formed on the template R3a. Thus, the QD film 221G and the electron-transporting material-containing film 233 are patterned to form, as a green EML (third EML), the EML 22G made of the QD film 221G on the HTL 21 of the green pixel PG, and to form the ETL 23G made of the electron-transporting material-containing film 233 as a first ETL of the green light-emitting element (third light-emitting element)(step S35).

As the developer used in steps S24, S28, and S32, for example, an aqueous alkaline developer (aqueous alkaline solution) such as an aqueous tetramethylammonium hydroxide (TMAH) solution is used.

Note that, in FIGS. 5 to 7, a case where a positive photoresist is used for each of the photoresist R1, the photoresist R2, and the photoresist R3 is illustrated as an example. However, the present embodiment is not limited to this case, and a negative photoresist may be used, instead of a positive photoresist. A negative photoresist has solubility against developers which may deteriorate due to exposure. For this reason, in a case where a negative photoresist is used, a mask that exposes pixels other than the pixels forming the template may be used as a mask used for exposure of the photoresist R1.

In addition, examples of the organic solvent (resist solvents) used in steps S27, S31, and S35 include a non-aqueous polar solvent such as dimethylsulfoxide (DMSO).

Next, the IL 24 is formed on the ETL 23R, the ETL 23G, and the ETL 23B in a solid state (step S36). Step S36 is a step of forming an insulating layer. As a result, a thin film IL 24 is formed on the ETL 23R, the ETL 23G, and the ETL 23B. To form the IL 24, a sputtering method, chemical vapor deposition (CVD), or the like can be used in a case where the IL 24 is made of an inorganic insulating material. In addition, in a case where the IL 24 is made of an organic insulating material such as a resin, a mist method such as a mist deposition method; a vapor deposition method; a coating method such as a spin coating method or a dip coating method, or the like can be used.

Next, the ETL 25 (second ETL) is formed in a solid state on the IL 24 by using a coating method or the like (step S37). Step S37 is a step of forming a second carrier transport layer. The electron-transporting material-containing film 233 can be formed by applying an electron-transporting material-containing liquid (fourth electron-transporting material-containing liquid) containing an electron transporting material and a solvent onto the IL 24 in a solid state and removing the solvent.

Note that, examples of a liquid-repellent-treatment method used in a case where the IL 24 has a liquid-repellent-treated surface include a mist method such as a mist deposition method; a vapor deposition method; a coating method such as a spin coating method or a dip coating method; and the like.

Next, the cathode 13 is formed on the ETL 25 as shown in FIG. 4 (step S38). Step S38 is a step of forming the upper layer electrode. A vapor deposition method, a sputtering method, or the like, for example, is used for forming the cathode 13 (film formation). The cathode 13 is a common electrode and is formed in a solid state on the ETL 25.

Accordingly, it is possible to form the display device 1 including the light-emitting element layer 3 in which the plurality of light-emitting elements ES including the light-emitting elements ESR, ESG, and ESB are formed, the ETL 23 provided for each of the light-emitting elements ES, and the ETL 25 provided on the ETL 23 in common to all the light-emitting elements ES, and the IL 24 provided between the ETL 23 and the ETL 25. According to the present embodiment, the display device 1 having the above-described configuration can be easily manufactured by using the patterning of the EML 22 of each of the light-emitting elements ES.

### Modified Example

FIGS. 1 and 2 illustrate a case in which the light-emitting element ES has a known structure in which the anode 11 is the lower layer electrode. However, the light-emitting element ES may have an inverted structure in which the cathode 13 is the lower layer electrode, or may have a structure in which, for example, the cathode 13, the ETL 25, the IL 24, the ETL 23, the EML 22, the HTL 21, and the anode 11 are layered on the substrate 2 in this order from the lower layer side.

### Second Embodiment

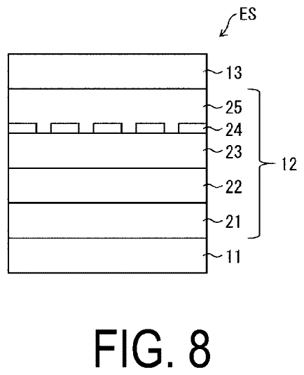

FIG. 8 is a cross-sectional view illustrating an example of a layered structure of a light-emitting element ES according to the present embodiment, and illustrates another example of the layered structure of the light-emitting element ES illustrated in FIG. 1.

The case where the IL 24 is formed in a thin film shape in the entire region between the ETL 23 and the ETL 25 overlapping the ETL 23 has been described as above as an example in the first embodiment. However, a configuration of the light-emitting element ES is not limited to this.

As described above, the IL may be provided at least partially between at least one carrier transport layer among the plurality of carrier transport layers and at least another carrier transport layer overlapping the at least one carrier transport layer. Thus, the IL may be formed in an island shape between at least one carrier transport layer and at least another carrier transport layer overlapping the at least one carrier transport layer, for example.

FIG. 8 illustrates a case where the IL 24 is formed in island shapes between the ETL 23 and the ETL 25 in the light-emitting element ES having the layered structure illustrated in FIGS. 1 and 2, as an example.

In a case where the IL 24 is formed in a thin film shape in the entire region between the ETL 23 and the ETL 25 as illustrated in FIG. 2 (that is, in a case where the IL 24 covers the entire inner surface of each pixel P), local current concentration can be suppressed as compared with the case where the ILs24 are scattered in island shapes as illustrated in FIG. 8. On the other hand, in a case where the IL 24 is formed in island shapes as illustrated in FIG. 8 and regions with the IL 24 and regions without the IL 24 are mixed in the pixel P, movement of carriers (electrons in the example illustrated in FIG. 8) in the portion where the IL 24 is formed is suppressed. On the other hand, in a portion where the IL 24 is not formed, carriers (electrons in the example illustrated in FIG. 8) can move between the ETL 23 and the ETL 25 without being affected by the IL 24. For this reason, the area through which carriers move is small for the same current density, so the total current can be reduced. By forming the IL sandwiched between the carrier transport layers in island shapes as described above, the amount of current can be easily adjusted.

Note that a method for forming the IL 24 in island shapes is not particularly limited. The IL 24 may be formed by, for example, thinly evaporating or spraying the material of the IL 24 in step S36 described above. That is, as an example, the island-shaped IL 24 may be formed by forming a thin and intermittent (sparse or non-uniform) film in such a manner. In addition, for example, after a resist material or the like is once layered, a resist residue left by removing (peeling off) or the like may be used as the island-shaped IL 24.

Although description is omitted, the IL may be formed in such island shapes also in the following embodiments.

### Third Embodiment

A light-emitting element ES in a display device 1 according to the present embodiment has the same layered structure as that of the light-emitting element ES illustrated in FIGS. 1 and 2. That is, the light-emitting element ES of the display device 1 according to the present embodiment has a configuration in which an anode 11, an HTL 21, an EML 22, an ETL 23, an IL 24, an ETL 25, and the cathode 13 are adjacent to each other and layered in this order from the lower layer side.

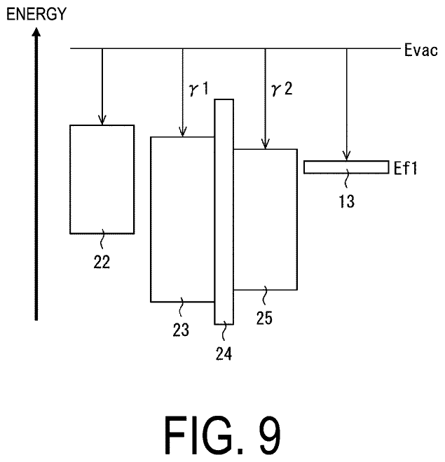

FIG. 9 is an energy diagram illustrating a relationship of electron affinities between layers of the light-emitting element ES according to the present embodiment.

For the light-emitting element ES according to the present embodiment, when the electron affinity of the ETL 23 is set to γ1 and the electron affinity of the ETL 25 is set to γ2, γ2>γ1 is satisfied as shown in FIG. 9. Note that the electron affinity of the ETL 23 (γ1) is represented by the absolute value of the energy difference between a vacuum level Evac and the lower end of the conduction band of the ETL 23, and the electron affinity of the ETL 25 (γ2) is represented by the absolute value of the energy difference between the vacuum level Evac and the lower end of the conduction band of the ETL 25. Although FIG. 9 also shows an example of the EML 22 and the cathode 13, the electron affinity of the EML 22 may be yl or greater, and the work function of the cathode 13 may be γ2 or less.

According to the present embodiment, γ2>γ1 is satisfied as described above, and in a case where the light-emitting element ES includes a plurality of ETLs, it is desirable that the ETLs closer to the cathode 13 have a larger electron affinity. As a result, the barrier to electron injection from the ETL 25 to the EML 22 can be lowered and the drive voltage can be lowered.

### Fourth Embodiment

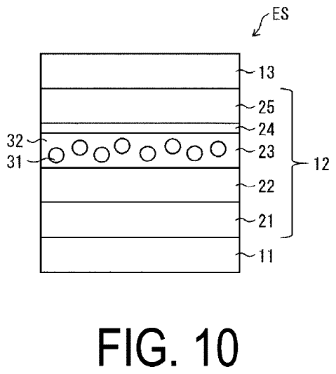

FIG. 10 is a cross-sectional view illustrating an example of a schematic configuration of a light-emitting element ES according to the present embodiment.

The light-emitting element ES illustrated in FIG. 10 has the same layered structure as that of the light-emitting element ES illustrated in FIGS. 1 and 2. However, in the light-emitting element ES illustrated in FIG. 10, the ETL 23 contains inorganic nanoparticles 31 having electron transportability and an insulating polymer 32.

In the present embodiment, the inorganic nanoparticles 31 preferably include inorganic nanoparticles made of an electron transporting material having electron transportability and containing an amphoteric element (that is, inorganic nanoparticles having electron transportability and containing an amphoteric element).

Examples of the electron transporting material containing such an amphoteric element include ZnO, MgZnO, and AlZnO.

Amphoteric elements such as Zn and Al react with both acids and bases. The inorganic nanoparticles 31 containing an amphoteric element are soluble in an alkaline aqueous solution, and can be patterned by using an alkaline aqueous solution. Therefore, for example, as shown in an embodiment to be described below, it is possible to etch the electron-transporting material-containing film constituting the ETL (ETL 23 in the example illustrated in FIG. 10) at the same time as the opening of the photoresist.

In addition, since the ETL 23 further includes the insulating polymer 32 as described above, it is possible to suppress an excessive amount of carrier current with the insulating polymer 32. In addition, by filling the gaps between the inorganic nanoparticles 31 with the insulating polymer 32, it is possible to prevent the solvents used for forming the layer above the ETL 23 from penetrating into the ETL 23 and further into the layer below the ETL 23 (for example, the EML 22) through the ETL 23.

In addition, examples of the insulating polymer 32 include at least one type selected from the group consisting of polyvinylpyrrolidone, polyvinyl alcohol (PVA), polystyrene (PS), poly(meth)acrylate, carboxymethylcellulose (CMC), polymethyl(meth)acrylate, polysilsesquioxane (PSQ), polydimethylsiloxane (PDMS), and the like. Among them, the insulating polymer 32 is preferably PVA. PVA is easily available, and the electron injection rate can be lowered by using PVA as the insulating polymer 32.

The proportion of the insulating polymer 32 in the ETL 23 (in other words, the proportion of the insulating polymer 32 with respect to the total amount of the inorganic nanoparticles 31 and the insulating polymer 32) is preferably in the range of 10 wt % or higher to 50 wt % or lower, and more preferably in the range of 10 wt % or higher to 35 wt % or lower. If the proportion of the insulating polymer 32 in the ETL 23 is higher than 50 wt %, the resistance becomes too high, which is not preferable. On the other hand, if the proportion of the insulating polymer 32 in the ETL 23 is lower than 10 wt %, there is a possibility that a sufficient effect of suppressing electrons cannot be obtained.

### Modified Example

FIG. 10 illustrates a case where the ETL 23 includes the inorganic nanoparticles 31 and the insulating polymer 32. However, the present embodiment is not limited to this case.

In the light-emitting element ES, at least one carrier transport layer among the plurality of layered carrier transport layers may contain the inorganic nanoparticles 31 and the insulating polymer 32.

Therefore, instead of the ETL 23, the ETL 25 may contain the inorganic nanoparticles 31 and the insulating polymer 32, or both the ETL 23 and the ETL 25 may contain the inorganic nanoparticles 31 and the insulating polymer 32.

### Fifth Embodiment

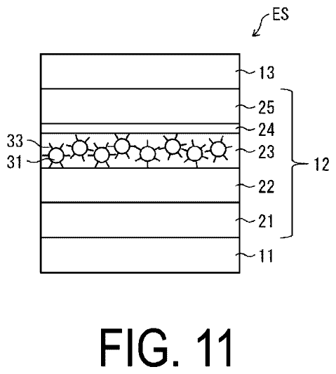

FIG. 11 is a cross-sectional view illustrating an example of a schematic configuration of a light-emitting element ES according to the present embodiment.

The light-emitting element ES illustrated in FIG. 11 has the same layered structure as that of the light-emitting element ES illustrated in FIGS. 1, 2, and 10. However, in the light-emitting element ES illustrated in FIG. 11, the ETL 23 contains the inorganic nanoparticles 31 and contains, as ligands 33, at least one of fluorinated organic ligands and inorganic ligands.

Also in the present embodiment, it is preferable that the inorganic nanoparticles 31 include inorganic nanoparticles made of an electron transporting material having electron transportability and containing an amphoteric element. Accordingly, as described above, patterning can be performed by using an alkaline aqueous solution, and for example, it is possible to etch the electron-transporting material-containing film constituting the ETL (ETL 23 in the example illustrated in FIG. 11) at the same time as the opening of the photoresist.

In addition, since the ETL 23 further includes the ligands 33, an excessive amount of carrier current can be suppressed. In addition, since the ETL 23 contains the ligands 33, the ligands 33 can be coordinated to the surfaces of the inorganic nanoparticles 31. With this configuration, the agglomeration of the inorganic nanoparticles 31 can be suppressed, and the intended optical characteristics are easily exhibited.

Note that, in the present embodiment, the term “coordination” indicates that the ligands 33 are adsorbed on the surfaces of the inorganic nanoparticles 31 (in other words, the ligands 33 modify the surfaces of the inorganic nanoparticles 31 (surface modification)). Here, the term “adsorb” indicates that a concentration of the ligands 33 on the surfaces of the inorganic nanoparticles 31 is increased more than that in the surroundings. The adsorption may be chemical adsorption in which there is a chemical bond between the inorganic nanoparticles 31 and the ligands 33, physical adsorption, or electrostatic adsorption. The ligands 33 may be bonded in a coordinate covalent bond, a common bond, an ionic bond, a hydrogen bond, or the like as long as it chemically affects the surface of the inorganic nanoparticles 31 through adsorption, or the ligand may not necessarily have to be bonded. In addition, in the present embodiment, not only a molecule or an ion coordinated to the surface of the inorganic nanoparticles 31 but also a molecule or an ion that can be coordinated but is not coordinated is referred to as a “ligand”.

Examples of the ligands 33 include a fluorinated organic ligand having a coordinating functional group to coordinate to the inorganic nanoparticles 31 and fluorine atoms. Typical examples of the coordinating functional group include at least one type of functional group selected from the group consisting of an amino (—NR₂) group, a phosphonic (—P(═O)(OR)₂) group, a phosphine (—PR₂) group, a phosphine oxide (—P(═O)R₂) group, a carboxyl (—C(═O)OH) group, a thiol (—SH) group, an alkoxysilyl (—Si(OR¹)ₙR²₃₋ₙ) group, a sulfonic acid (—S(═O)₂OR) group, and an isocyanate (—N═C═O) group.

Examples of the fluorinated organic ligand include 2H,2H,3H,3H-heptadecafluoroundecanoic acid, 3,3,4,4,5,5,6,6,7,7,8,8,9,9,10,10,10-heptadecafluoro-1-decanethiol, as well as FHPA, FOPA, FDPA, and the like exemplified as the fluorine compounds. A single type of these fluorinated organic ligands may be used alone, or two or more types may be mixed and used as appropriate.

In addition, in a case where the ligands 33 are, for example, inorganic ligands, the compound used for the inorganic ligand is present as anions and cations. Among these anions and cations, since the anions are negatively charged, they are attracted as ligands to the positively charged surfaces of the inorganic nanoparticles 31.

Examples of the anions used as the inorganic ligand include, but are not limited to, halogen anions such as fluoride ions. Examples of the anions include F⁻, Cl⁻, Br⁻, I⁻, S²⁻, Se²⁻, Te²⁻, HS⁻, SnS₄⁴⁻, and Sn₂S₆⁴⁻. Examples of the cation serving as counter ions include H⁺ and NH₄⁺.

The type of the ligand included in the ETL 23 can be identified by combining a plurality of analysis methods, for example, a matrix-assisted laser desorption ionization-time of flight-mass spectrometry (MALDI-TOF-MS) method, a liquid chromatography with tandem mass spectrometry (LC-MS/MS) method, and a time-of-flight secondary ion mass spectrometry (TOF-SIMS) method.

A matrix-assisted laser desorption-ionization (MALDI) method is a method in which a matrix mixture is irradiated with a nitrogen laser beam (wavelength=337 nm) to rapidly (for several nanoseconds) heat a portion from the outermost surface to 100 nm to vaporize the matrix mixture.

The time-of-flight mass spectrometry (TOF-MS) method is a method of performing mass spectrometry by utilizing the fact that the time of flight of ions varies depending on a difference in mass-to-charge ratio m/z value.

The liquid chromatography with tandem mass spectrometry (LC-MS/MS) method is a method for identifying a molecule with an apparatus in which a high performance liquid chromatograph (HPLC) and a triple quadrupole mass spectrometer (MS/MS) are combined. The LC-MS/MS can obtain a further separated mass spectrum with the connected MS unit than that of the LC-MS, and is thus superior in the identification of molecules.

In the time-of-flight secondary ion mass spectrometry (TOF-SIMS) method, when a sample is irradiated with a primary ion beam under ultra-high vacuum, secondary ions are emitted from an extreme surface (1 to 3 nm) of the sample. The secondary ions are introduced into a time-of-flight (TOF) mass spectrometer to obtain a mass spectrum of the outermost surface of the sample. At this time, a primary ion irradiation amount is reduced to a low level, whereby a surface component can be detected as molecular ions maintaining the chemical structure or a partially cleaved fragment, and information about the elemental composition or chemical structure of the outermost surface can be obtained.

In addition, the ligand may be identified by precipitating the solid content contained in the electron-transporting material-containing liquid containing the inorganic nanoparticles 31 and the ligand, and subjecting the precipitate or the residue to elemental analysis by using scanning electron microscope-energy dispersive X-ray spectroscopy (SEM-EDX). Alternatively, the ligand may be identified by taking an SEM image of a cross section of the light-emitting element ES and also performing elemental analysis.

In addition, depending on the ligand to coordinate, whether the coordination is present can be confirmed by using, for example, measurement using Fourier transform infrared spectroscopy (FT-IR)(FT-IR measurement). For example, in a case where the ligand coordinated to the inorganic nanoparticles includes, for example, a carboxy group (—COOH group), an amino group (—NH₂ group), a phosphonic group (—PO group), or the like, oscillations observed in the FT-IR measurement slightly differ between the uncoordinated state and the coordinated state, and the detection peak shifts. This allows the presence or absence of coordination of the ligands to the inorganic nanoparticles 31 to be confirmed.

### Modified Example

Note that FIG. 11 also illustrates a case in which the ETL 23 contains the inorganic nanoparticles 31 and the ligands 33. However, the present embodiment is not limited to this case.

In the light-emitting element ES, at least one carrier transport layer among the plurality of layered carrier transport layers may contain the inorganic nanoparticles 31 and the ligands 33.

Therefore, instead of the ETL 23, the ETL 25 may contain the inorganic nanoparticles 31 and the ligands 33, or both the ETL 23 and the ETL 25 may contain the inorganic nanoparticles 31 and the ligands 33.

### Sixth Embodiment

In the first embodiment, the case where each light-emitting element ES includes the HTL 21, the EML 22, the ETL 23, the IL 24, and the ETL 25 as the function layer 12 between the anode 11 and the cathode 13 has been described. However, the display device 1 according to the disclosure is not limited thereto.

In the display device 1, at least one light-emitting element ES may include a plurality of carrier transport layers and at least one IL layered between the first electrode and the EML.

Therefore, the light-emitting element ESR, the light-emitting element ESG, and the light-emitting element ESB may have layered structures different from each other, and the numbers of carrier transport layers layered may differ in the light-emitting element ESR, the light-emitting element ESG, and the light-emitting element ESB. In addition, the number of ILs in the light-emitting element ESR, the light-emitting element ESG, and the light-emitting element ESB may be different from each other.

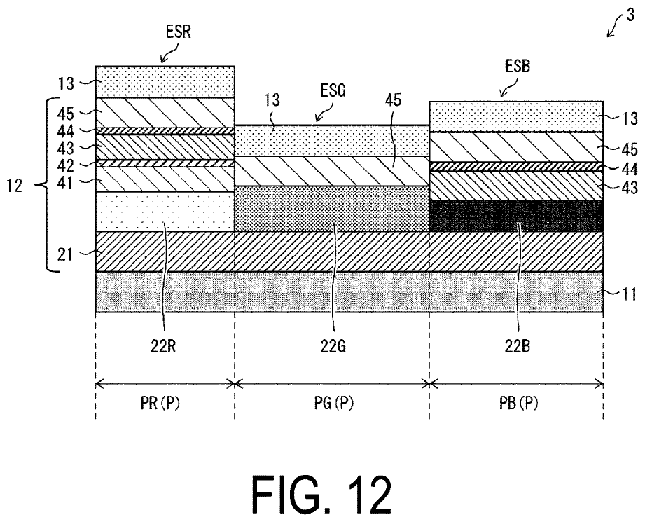

FIG. 12 is a cross-sectional view illustrating an example of a light-emitting element layer 3 in a display device 1 according to the present embodiment. Note that no banks BK are illustrated in FIG. 12 for convenience of illustration.

The light-emitting element ESR illustrated in FIG. 12 has a configuration in which an anode 11, an HTL 21, an EML 22R, an ETL 41 (first ETL or first carrier transport layer), an IL 42 (first IL), an ETL 43 (second ETL or second carrier transport layer), an IL 44 (second IL), an ETL 45 (third ETL or third carrier transport layer), and a cathode 13 are layered to be adjacent to each other in this order from the lower layer side. The light-emitting element ESR includes the HTL 21, the EML 22, the ETL 41, the IL 42, the ETL 43, the IL 44, and the ETL 45 as a function layer 12.

In addition, the light-emitting element ESB illustrated in FIG. 12 has a configuration in which the anode 11, the HTL 21, an EML 22B, the ETL 43 (first ETL or first carrier transport layer), the IL 44, the ETL 45 (second ETL or second carrier transport layer), and the cathode 13 are layered to be adjacent to each other in this order from the lower layer side. The light-emitting element ESB includes the HTL 21, the EML 22B, the ETL 43, the IL 44, and the ETL 45 as the function layer 12.

In addition, the light-emitting element ESG illustrated in FIG. 12 has a configuration in which the anode 11, the HTL 21, an EML 22G, the ETL 45, and the cathode 13 are layered to be adjacent to each other in this order from the lower layer side. The light-emitting element ESG includes the HTL 21, the EML 22G, and the ETL 45 as the function layer 12.

In the present embodiment, the plurality of ETLs layered in each of the light-emitting elements ES are referred to as a first ETL, a second ETL, and a third ETL in order from the lower layer side for convenience of description. Similarly, in the present embodiment, in a case where a plurality of ILs are provided in each of the light-emitting elements ES, these ILs are referred to as a first IL and a second IL in order from the lower layer side for convenience of description.

As described above, in the display device 1 according to the present embodiment, the light-emitting element ESR includes three layers of ETLs between the cathode 13 and the EML 22, and the ILs are provided between the ETLs. For this reason, the light-emitting element ESR includes two layers of IL. In addition, in the display device 1, the light-emitting element ESB includes two layers of ETL between the cathode 13 and the EML 22, and an IL is provided between the ETLs. For this reason, the light-emitting element ESR includes only one layer of IL. In the display device 1, the light-emitting element ESG includes only one layer of ETL between the cathode 13 and the EML 22, and no IL is provided in the light-emitting element ESG. As described above, in the display device 1, the number of ETLs layered may differ in the light-emitting element ESR, the light-emitting element ESB, and the light-emitting element ESG.

Next, a manufacturing method for the display device 1 according to the present embodiment will be described. In manufacturing steps for the display device 1, steps other than the step of forming the light-emitting element layer 3 (step S4) are the same as those in the first embodiment. Thus, only the step of forming the light-emitting element layer 3 (step S4) will be described below.

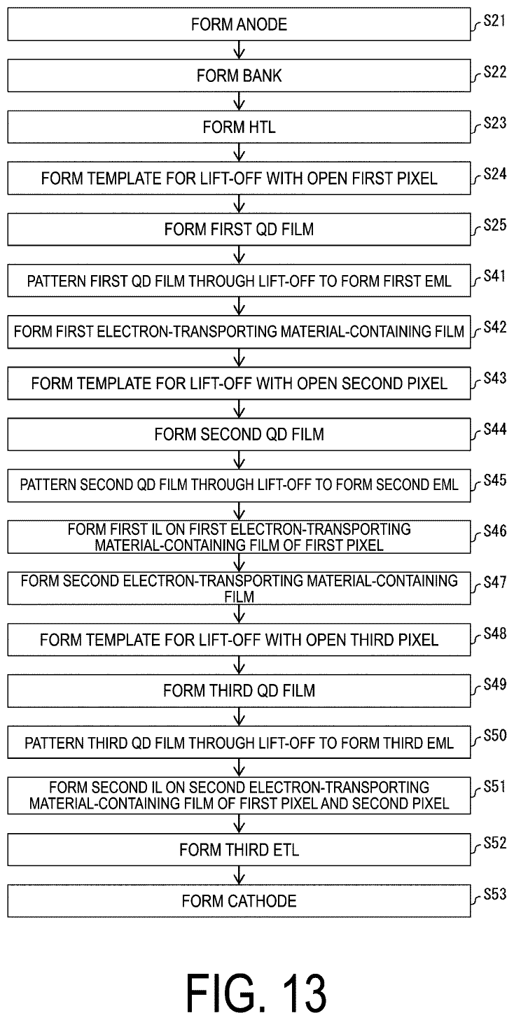

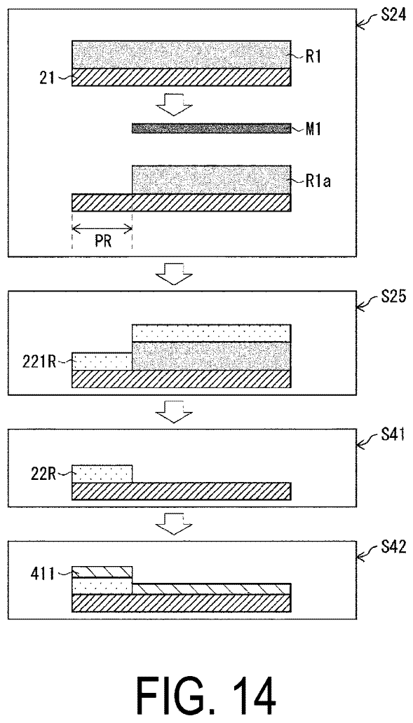

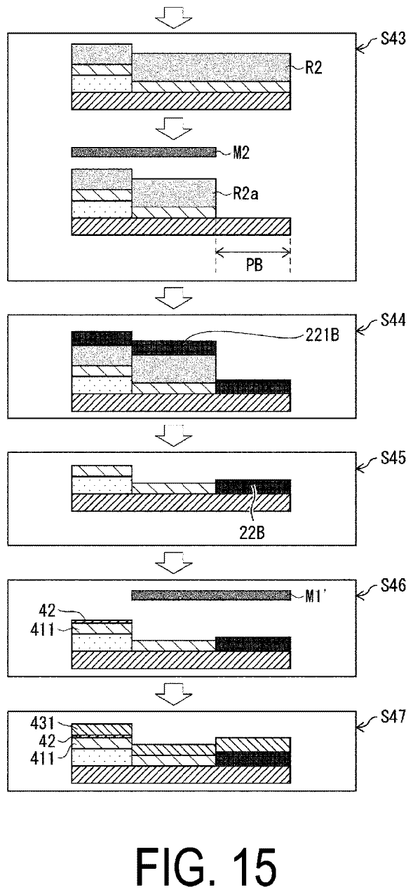

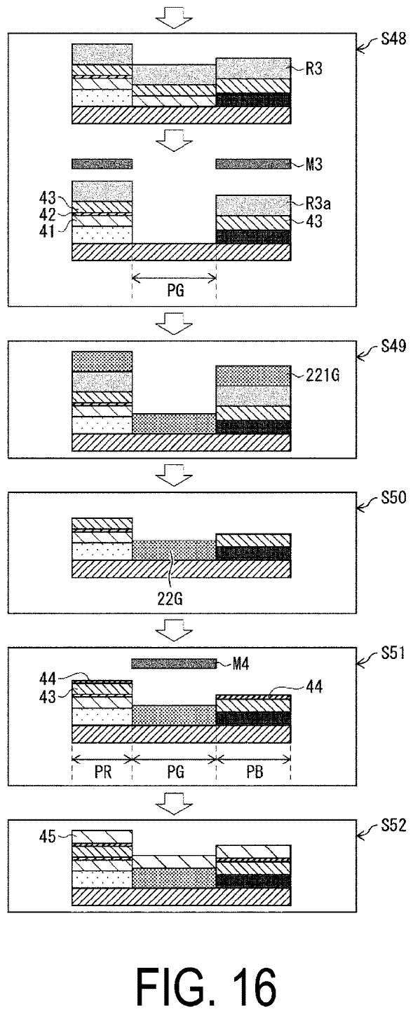

FIG. 13 is a flowchart showing an example of the step of forming the light-emitting element layer 3 according to the present embodiment. FIG. 14 is a cross-sectional view illustrating an example of steps S24 to S42 shown in FIG. 13. FIG. 15 is a cross-sectional view illustrating an example of steps S43 to S47 shown in FIG. 13. FIG. 16 is a cross-sectional view illustrating an example of steps S48 to S52 shown in FIG. 13.

In the step of forming the light-emitting element layer 3 (step S4) according to the present embodiment, first, the anode 11, banks BK, and the HTL 21 are formed in this order (step S21 to step S23) as shown in FIG. 13 in the same manner as in step S21 to step S23 shown in FIG. 4.

Next, a template R1a for lift-off with an opening in the region corresponding to a red pixel PR (first pixel) is formed through photolithography (step S24) as shown in FIGS. 13 and 14, in the same manner as in step S24 shown in FIGS. 4 and 5. To be specific, first, a photoresist R1 for a template is formed in a solid state over the entire pixel region on the HTL 21 serving as a base layer. Next, by using a mask M1 with an opening in the region corresponding to the red pixel PR, exposure is performed with ultraviolet rays (UV), and then development is performed with a developer. As a result, the template R1a is formed.

Next, on the HTL 21 on which the template R1a is formed, a QD film 221R containing red QDs is formed as a red QD film (first QD film) in a solid state over the entire pixel region (step S25) in the same manner as in step S25 shown in FIGS. 4 and 5. The steps up to this point are the same as the steps of forming the light-emitting element layer 3 shown in FIGS. 4 and 5.

Next, the template R1a is removed with an organic solvent to lift off the QD film 221R formed on the template R1a. As a result, the QD film 221R is patterned to form an ELM 22R made of the QD film 221R as a red EML (first EML) on the HTL 21 for the red pixel PR (step S41).

Next, an electron-transporting material-containing film 411 (first electron-transporting material-containing film) containing an electron transporting material is formed in a solid state on the HTL 21 to cover the EML 22R (step S42). The electron-transporting material-containing film 411 can be formed by applying the electron-transporting material-containing liquid (first electron-transporting material-containing liquid) containing an electron transporting material (first electron transporting material) and a solvent onto the HTL 21 on which the EML 22R has been formed in a solid state and removing the solvent. In the present embodiment, an electron-transporting material-containing liquid containing inorganic nanoparticles 31 containing an amphoteric element as an electron transporting material is used as the electron-transporting material-containing liquid.

Next, a template R2a for lift-off in which a region corresponding to a blue pixel PB (second pixel) is opened is formed through photolithography (step S43) as shown in FIGS. 13 and 15, in the same manner as in step S28 shown in FIGS. 4 and 6. To be specific, first, a photoresist R2 for a template is formed in a solid state over the entire pixel region to cover the EML 22R and the electron-transporting material-containing film 411 on the HTL 21 serving as a base layer. Next, by using a mask M2 in which the region corresponding to the blue pixel PB is opened, exposure is performed with UV, and then development is performed with a developer.

The inorganic nanoparticles 31 containing an amphoteric element are soluble in an alkaline aqueous solution, and can be patterned by using an alkaline aqueous solution as described above. Thus, the electron-transporting material-containing film 411 can be etched simultaneously with opening of the photoresist R2. Therefore, the photoresist R2 and the electron-transporting material-containing film 411 for the blue pixel PB are simultaneously etched and removed through the development with the developer in step S43 described above. As a result, the template R2a exposing only the HTL 21 of the blue pixel PB serving as the base layer is formed.

Next, a QD film 221B containing blue QDs is formed in a solid state over the entire pixel region as a blue QD film (second QD film)(step S44) on the HTL 21 on which the template R2a, the EML 22R, and the electron-transporting material-containing film 411 are formed, in the same manner as in step S29 shown in FIGS. 4 and 6.

Next, the template R2a is removed with an organic solvent to lift off the QD film 221B on the template R2a in the same manner as in step S31 shown in FIGS. 4 and 6. As a result, the QD film 221B is patterned to form an ELM 22B made of the QD film 221B as a blue EML (second EML) on the HTL 21 for the blue pixel PB (step S45).

Next, by using a mask M1′ with an opening in the region corresponding to the red pixel PR, an IL 42 is selectively formed on the electron-transporting material-containing film 411 for the red pixel PR as a first IL in the light-emitting element ESR (step S46). Note that, although FIG. 15 illustrates a case in which the mask M1′ having an opening in the region corresponding to the red pixel PR is used to form the IL 42, it is needless to say that the IL 42 may be formed through photolithography by using a photoresist.

In addition, although the case where the template R2a is entirely removed in step S45 has been described with reference to FIG. 15, the template R2a (resist) may be partially left in step S45 to form the IL 42. In addition, the residue (resist residue) of the template R2a left in the lift-off process in step S45 may be used as an island-shaped IL 42. At this time, the template R2a of the green pixel PG may be completely removed or may be left. The template R2a remaining in the green pixel PG is removed with a developer in step S48 to be described later.

Next, an electron-transporting material-containing film 431 (second electron-transporting material-containing film) containing an electron transporting material is formed in a solid state to cover the IL 42 for the red pixel PR, the electron-transporting material-containing film 411 for the green pixel PG, and the EML 22B for the blue pixel PB (step S47). The electron-transporting material-containing film 431 can be formed by applying an electron-transporting material-containing liquid (second electron-transporting material-containing liquid) containing an electron transporting material (second electron transporting material) and a solvent onto the IL 42, the electron-transporting material-containing film 411, and the EML 22B, in a solid state and removing the solvent. In the present embodiment, an electron-transporting material-containing liquid containing inorganic nanoparticles 31 containing an amphoteric element as an electron transporting material is used as the electron-transporting material-containing liquid.

Next, a template R3a for lift-off with an opening in the region corresponding to a green pixel PB (third pixel) is formed through photolithography (step S48) as shown in FIGS. 13 and 16, in the same manner as in step S32 shown in FIGS. 4 and 7. To be specific, first, a photoresist R3 for a template is formed in a solid state over the entire pixel region on the electron-transporting material-containing film 431. Next, by using a mask M3 with an opening in the region corresponding to the green pixel PG, exposure is performed with UV, and then development is performed with a developer.

In the green pixel PG, the electron-transporting material-containing film 431 is layered on the electron-transporting material-containing film 411. Since the electron-transporting material-containing film 411 and the electron-transporting material-containing film 431 each contain the inorganic nanoparticles 31 containing an amphoteric element as described above, patterning can be performed by using an alkaline aqueous solution. For this reason, the photoresist R3, the electron-transporting material-containing film 411, and the electron-transporting material-containing film 431 for the green pixel PG are simultaneously etched and removed through the development with the developer in step S48 described above. As a result, the template R3a exposing only the HTL 21 of the green pixel PG serving as the base layer is formed, and the electron-transporting material-containing film 411 and the electron-transporting material-containing film 431 are patterned. As a result, in the red pixel PR, the ETL 41 formed of the electron-transporting material-containing film 411 is formed as a first ETL of the light-emitting element ESR, and the ETL 43 formed of the electron-transporting material-containing film 431 is formed as a second ETL of the light-emitting element ESR. In addition, in the blue pixel PB, the ETL 43 formed of the electron-transporting material-containing film 431 is formed as a first ETL of the light-emitting element ESB.

Next, a QD film 221G containing green QDs is formed as a green QD film (third QD film) in a solid state over the entire pixel region on the HTL 21 on which the template R3a has been formed (step S49), in the same manner as in step S33 shown in FIGS. 4 and 7.

Next, the template R3a is removed with an organic solvent to lift off the QD film 221G on the template R3a in the same manner as in step S35 shown in FIGS. 4 and 7. As a result, the QD film 221G is patterned to form the ELM 22G made of the QD film 221G as a green EML (third EML) on the HTL 21 for the green pixel PG (step S50).

Next, by using a mask M4 with openings in the regions corresponding to the red pixel PR and the green pixel PG, the IL 44 is selectively formed as a second IL in the light-emitting element ESR and a first IL in the light-emitting element ESB on the electron-transporting material-containing film 431 for the red pixel PR and the blue pixel PB (step S51). Note that, although FIG. 16 illustrates a case where the mask M4 is used to form the IL 44, the IL 44 may be formed through photolithography using a photoresist. In addition, the template R3a may be used to form the IL 44 in the same manner as the IL 42.

Next, the ETL 45 is formed in a solid state by using a coating method or the like to cover the IL 44 in the red pixel PR, the EML 22G in the green pixel PG, and the IL 44 in the blue pixel PB (step S52). The ETL 45 can be formed by applying an electron-transporting material-containing liquid (third electron-transporting material-containing liquid) containing an electron transporting material and a solvent onto the IL 44 in a solid state and removing the solvent.

Next, the cathode 13 is formed on the ETL 45 as shown in FIG. 13 (step S53), in the same manner as in step S38 shown in FIG. 4. Thus, it is possible to form the light-emitting element layer 3 including the light-emitting element ESR, the light-emitting element ESB, and the light-emitting element ESG illustrated in FIG. 12.

The same material as that of the IL 24 in the first to fifth embodiments may be used for the IL 42 and IL 44. In addition, the same materials as those of the ETL 23 and the ETL 25 in the first to fifth embodiments may be used for the ETL 41, the ETL 43, and the ETL 45.

Note that, although the case where the IL 42 and the IL 44 have a thin film shape is illustrated in FIGS. 12 and 14 to 16 as an example, the present embodiment is not limited thereto. Both the IL 42 and the IL 44 may have an island shape, or one of the IL 42 and the IL 44 may have a thin film shape and the other may have an island shape.

### Seventh Embodiment

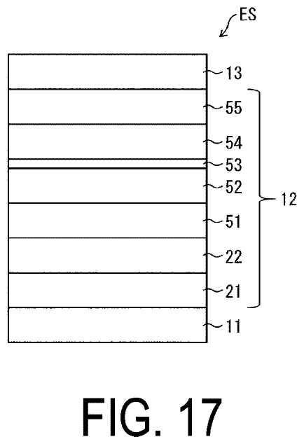

FIG. 17 is a cross-sectional view illustrating an example of a layered structure of a light-emitting element ES according to the present embodiment.

The light-emitting element ES illustrated in FIG. 17 has a configuration in which an anode 11, an HTL 21, an EML 22, an ETL 51, an ETL 52, an IL 53, and ETL 54, an ETL 55, and a cathode 13 are layered in this order from the lower layer side as an example.

As described above, the IL may be provided between at least one carrier transport layer among the plurality of carrier transport layers and at least another carrier transport layer, and the IL does not necessarily need to be provided between all the layered carrier transport layers.

According to the present embodiment, since the IL 53 is provided between the ETL 52 and the ETL 54, it is possible to reduce the amount of electrons injected between the ETL 52 and the ETL 54, suppress an excessive amount of electrons from being injected from the cathode 13 to the EML 22, and improve the balance of carriers. As a result, also in the present embodiment, the rate of non-radiative recombination in the EML 22 can be lowered, and the improvement in luminous efficiency can be realized. Thus, also in the present embodiment, it is possible to provide the display device 1 with higher luminous efficiency and reliability as a light-emitting device.

Note that, although a case where the IL 53 is provided between the ETL 52 and the ETL 54 is illustrated in FIG. 17 as an example, the present embodiment is not limited thereto.

The IL may be provided at least one of between the ETL 51 and the ETL 52, between the ETL 52 and the ETL 54, and between the ETL 54 and the ETL 55. In addition, as described above, the number of ETLs layered and the number of ILs layered are not particularly limited. In addition, each IL may have a thin film shape or an island shape. In addition, a thin film-shaped IL and an island-shaped IL may be provided.

For the IL (for example, IL 53), the same material as that of the IL 24 in the first to fifth embodiments and the IL 42 and the IL 44 in the sixth embodiment may be used. In addition, for the ETL 51, the ETL 54, and the ETL 55, the same materials as those of the ETL 23 and the ETL 25 in the first to fifth embodiments and the ETL 41, the ETL 43, and the ETL 45 in the sixth embodiment may be used.

In addition, the IL may only be provided between at least one carrier transport layer among the plurality of carrier transport layers and at least another carrier transport layer adjacent to the at least one carrier transport layer as described above. Therefore, the IL may be provided at least partially between the EML 22 and the carrier transport layer (for example, ETL 51) adjacent to the EML 22.

However, in a case where an insulating substance is in contact with the QD layer, the insulating substance may damage the QDs. For this reason, it is preferable that the insulating substance should not be in contact with the QD layer.

Thus, the IL is preferably provided only between at least one carrier transport layer among the plurality of carrier transport layers and at least another carrier transport layer.

Therefore, in a case where the ETL 51, the ETL 52, the ETL 54, and the ETL 55 are included as ETLs as described above, it is more preferable that the IL be provided only in at least one spot, for example, between the ETL 51 and the ETL 52, between the ETL 52 and the ETL 54, and between the ETL 54 and the ETL 55.

As a result, it is possible to prevent the EML from being damaged by forming the IL in contact with the EML, and to provide a light-emitting device having higher luminous efficiency and reliability.

### Eighth Embodiment

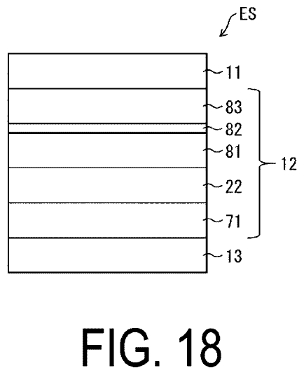

FIG. 18 is a cross-sectional view illustrating an example of a layered structure of a light-emitting element ES according to the present embodiment.

In the first to seventh embodiments, the case where the first electrode is the cathode 13, the second electrode is the anode 11, and a plurality of ETLs are provided as carrier transport layers between the cathode 13 and the EML 22 has been described. However, the disclosure is not limited thereto, and the first electrode may be the anode 11, the second electrode may be the cathode 13, and the function layer 12 may include a plurality of HTLs as carrier transport layers between the anode 11 and the EML 22.

FIG. 18 is a diagram schematically illustrating an example of a layered structure of the light-emitting element ES according to the present embodiment.

As illustrated in FIG. 18, the light-emitting element ES according to the present embodiment has a configuration in which a cathode 13, an ETL 71, an EML 22, an HTL 81 (first HTL or first carrier transport layer), an IL 82, an HTL 83 (second HTL or second carrier transport layer), and an anode 11 are adjacent to each other and layered in this order from the lower layer side. Thus, the cathode 13 serving as a lower layer electrode functions as a so-called pixel electrode (island-shaped lower layer electrode) and is provided on a substrate 2 in an island shape for each light-emitting element ES (in other words, for each pixel). The anode 11 serving as an upper layer electrode is provided as a common electrode (common upper electrode) in common to all the light-emitting elements ES (in other words, all the pixels). The light-emitting elements ES function as light sources that light up each of the pixels.

However, the present embodiment is not limited thereto, and may have, for example, a configuration in which the anode 11, the HTL 83, the IL 82, the HTL 81, the EML 22, the ETL 71, and the cathode 13 are layered in this order from the lower layer side. That is, the light-emitting element ES may have an inverted structure as illustrated in FIG. 18 or may have a known structure.

The balance of carriers varies depending on the material of each layer (function layer) between the anode 11 and the cathode 13, and a combination of a layer thickness, an energy level, and the like. For example, organic materials have a lower carrier mobility than the carrier mobility of inorganic materials. In addition, when a layer thickness is changed, the distribution of a voltage applied to each layer is changed, so the balance of carriers injected into the EML 22 is changed.

In addition, although the case where the light-emitting element ES is a QLED has been described as an example in the first to seventh embodiments, the light-emitting element ES may be a QLED, an organic light-emitting diode (OLED), or an inorganic light-emitting diode (IOLED). In a case where the light-emitting element ES is an OLED or an IOLED, the EML 22 is formed of an organic light-emitting material or an inorganic light-emitting material, for example, a low molecular weight fluorescent (or phosphorescent) dye and a metal complex.

According to the present embodiment, the HTL 81 and the HTL 83 are provided with the IL 82 interposed therebetween as described above. For this reason, in a case where the amount of holes injected is greater than the amount of electrons injected to the EML 22 (for example, a case of a combination with a lower carrier mobility of the ETL than that of the HTL), it is possible to reduce the amount of electrons injected between the HTL 81 and the HTL 83. As a result, it is possible to suppress an excessive amount of holes from being injected from the anode 11 to the EML 22 and improve the balance of carriers. As a result, also in the present embodiment, the rate of non-radiative recombination in the EML 22 can be lowered, and the improvement in luminous efficiency can be realized. Thus, also in the present embodiment, it is possible to provide, for example, the display device 1 with higher luminous efficiency and reliability as a light-emitting device.

For the IL 82, the same materials as the IL 24 in the first to fifth embodiments, the IL 42 and the IL 44 in the sixth embodiment, and the IL 53 in the seventh embodiment can be used. In addition, for the ETL 71, the same materials as the ETL 23 and the ETL 25 in the first to fifth embodiments, the ETL 41, the ETL 43, and the ETL 45 in the sixth embodiment, and the ETL 51, the ETL 54, and the ETL 55 in the seventh embodiment can be used. The same material as that of the HTL 21 in the first to seventh embodiments can be used for the HTL 81 and the HTL 83.

Even in a case where the IL is provided between a plurality of HTLs as described above, the IL may be provided at least partially between at least one carrier transport layer among a plurality of carrier transport layers (HTLs in the present embodiment) and at least another carrier transport layer overlapping the at least one carrier transport layer. Therefore, also in this case, the IL may be formed in a thin film shape or in an island shape between the plurality of HTLs layered with the IL interposed therebetween.

In addition, in the case where a plurality of HTLs are layered as described above, it is preferable that an HTL closer to the anode 11 have a smaller ionization potential (ionization energy). Therefore, in the light-emitting element ES illustrated in FIG. 18, in a case where the ionization potential of the HTL 81 is γ21 and the ionization potential of the HTL 83 is γ22, it is preferable that γ21 is greater than γ22 (γ21>γ22). The ionization potential (γ21) of the HTL 81 is represented by the absolute value of the energy difference between a vacuum level Evac and an upper end of the valence band of the HTL 81, and the ionization potential (γ22) of the HTL 83 is represented by the absolute value of the energy difference between the vacuum level Evac and the upper end of the valence band of the HTL 83.

In a case where the light-emitting element ES has a plurality of HTLs, the HTLs closer to the anode 11 have a smaller ionization potential as described above, so the hole injection barrier from the HTL 83 to the EML 22 can be lowered and the drive voltage can be lowered.

Note that, even in a case where a plurality of HTLs are layered with the IL interposed therebetween as described above, at least one HTL of the plurality of HTLs may contain inorganic nanoparticles having carrier transportability (in this case, a hole transport property) and an insulating polymer. Examples of the inorganic nanoparticles having the hole transportability include nanoparticles of inorganic materials exemplified as the hole transporting material in the first embodiment. In addition, as the insulating polymer, the insulating polymer 32 exemplified in the fourth embodiment can be used.

In addition, in the case where the plurality of HTLs are layered with the IL interposed therebetween as described above, at least one HTL of the plurality of HTLs may also contain the above-described inorganic nanoparticles having carrier transportability (in this case, hole transportability) and a ligand. In this case, the ligand 33 such as a fluorinated organic ligand, an inorganic ligand, or the like exemplified in the fifth embodiment can be used as the above-described ligand. Thus, also in the present embodiment, the HTL may contain at least one of a fluorinated organic ligand and an inorganic ligand as a ligand.

In addition, in the present embodiment, the number of HTLs layered and the number of ILs layered are not particularly limited. Three or more layers of HTL may be layered, and two or more layers of IL may be provided. In this case, each IL may have a thin film shape or an island shape. In addition, a thin film-shaped IL and an island-shaped IL may be provided.

In addition, in the present embodiment, for example, the IL may be provided at least partially between the EML 22 and the HTL adjacent to the EML 22 (for example, the HTL 81).

However, also in the present embodiment, for the same reason as that described in the seventh embodiment, in a case where a plurality of HTLs are provided as carrier transport layers as described above, the IL is preferably provided only between at least one HTL among the plurality of HTLs and at least another HTL.

As a result, it is possible to prevent the EML from being damaged by forming the IL in contact with the EML, and to provide a light-emitting device having higher luminous efficiency and reliability.

### Modified Example

In addition, the case where a plurality of carrier transport layers are layered either between the EML 22 and the cathode 13 or between the EML 22 and the anode 11 has been described in the first to eighth embodiments. However, the disclosure is not limited thereto. The function layer 12 may include a plurality of ETLs as a carrier transport layer between the EML 22 and the cathode 13 and may include a plurality of HTLs as carrier transport layers between the EML 22 and the anode 11. In this case, the formation position of the IL may be determined based on the relationship of the amount of current, the balance of carriers, and the like, and at least one IL may be provided in at least a part between the HTLs or at least a part between the ETLs. Note that, also in this case, in the light-emitting element ES, one of the anode 11 and the cathode 13 may be an upper layer electrode and the other may be a lower layer electrode, and the light-emitting element ES may have a known structure or an inverted structure.

In addition, in the first to eighth embodiments, the case where the light-emitting device according to the disclosure is a display device and the light-emitting device includes a plurality of light-emitting elements ES has been described. However, the light-emitting device according to the disclosure is not limited thereto. The light-emitting device may include at least one light-emitting element ES according to the disclosure, and the light-emitting device may be, for example, an illumination device, or the like.

The disclosure is not limited to the embodiments described above, various modifications may be made within the scope of the claims, and an embodiment obtained by appropriately combining technical approaches disclosed in different embodiments also falls within the technical scope of the disclosure. Furthermore, novel technical features can be formed by combining the technical approaches disclosed in each of the embodiments.

1. A light-emitting device comprising:
at least one light-emitting element including a first electrode and a second electrode facing each other, and a light-emitting layer provided between the first electrode and the second electrode,
wherein at least one of the light-emitting elements includes a plurality of carrier transport layers and at least one insulating layer, both being layered between the first electrode and the light-emitting layer, and
the insulating layer is provided at least partially between at least one carrier transport layer among the plurality of carrier transport layers and at least another carrier transport layer overlapping the at least one carrier transport layer.

2. The light-emitting device according to claim 1,
wherein the insulating layer is provided only between the at least one carrier transport layer and at least the other carrier transport layer overlapping the at least one carrier transport layer.

3. The light-emitting device according to claim 1,
wherein the insulating layer is formed in a thin film shape in an entire region between the at least one carrier transport layer and at least the other carrier transport layer overlapping the at least one carrier transport layer.

4. The light-emitting device according to claim 1,
wherein the insulating layer is provided in an island shape between the at least one carrier transport layer and at least the other carrier transport layer overlapping the at least one carrier transport layer.

5. The light-emitting device according to claim 1,
wherein the insulating layer contains a photosensitive insulating material having photosensitivity.

6. The light-emitting device according to claim 1,
wherein at least a part of the insulating layer contains a liquid-repellent material having liquid repellency against an organic solvent.

7. The light-emitting device according to claim 6,
wherein the liquid-repellent material is at least one type selected from the group consisting of a fluorine compound, a silicone resin, and an acrylic resin.

8. The light-emitting device according to claim 6,
wherein the liquid-repellent material contains a fluorine compound.

9. The light-emitting device according to claim 1,
wherein the first electrode is a cathode,
the second electrode is an anode, and
each of the carrier transport layers is an electron transport layer.

10. The light-emitting device according to claim 9,
wherein the electron transport layers closer to the cathode have a greater electron affinity.

11. The light-emitting device according to claim 1,
wherein the first electrode is an anode,
the second electrode is a cathode, and
each of the carrier transport layers is a hole transport layer.

12. The light-emitting device according to claim 11,
wherein the hole transport layers closer to the anode have a smaller ionization potential.

13. The light-emitting device according to claim 9,
wherein the at least one carrier transport layer among the plurality of carrier transport layers contains inorganic nanoparticles having electron transportability and containing an amphoteric element.

14. The light-emitting device according to claim 13,
wherein the at least one carrier transport layer of the plurality of carrier transport layers further contains an insulating polymer.

15. The light-emitting device according to claim 1,
wherein the at least one carrier transport layer among the plurality of carrier transport layers contains inorganic nanoparticles having carrier transportability and an insulating polymer.

16. The light-emitting device according to claim 14,
wherein the insulating polymer is at least one type selected from the group consisting of polyvinylpyrrolidone, polyvinyl alcohol, polystyrene, poly(meth)acrylate, carboxymethylcellulose, polymethyl(meth)acrylate, polysilsesquioxane, and polydimethylsiloxane.

17. (canceled)

18. The light-emitting device according to claim 1,
wherein the at least one carrier transport layer among the plurality of carrier transport layers contains inorganic nanoparticles having carrier transportability and at least one of a fluorinated organic ligand and an inorganic ligand.

19. The light-emitting device according to claim 13,
wherein the at least one carrier transport layer of the plurality of carrier transport layers further contains at least one of a fluorinated organic ligand and an inorganic ligand.

20. The light-emitting device according to claim 1, comprising:
a plurality of the light-emitting elements,
wherein the plurality of the light-emitting elements include
a first light-emitting element configured to emit light of a first color,
a second light-emitting element configured to emit light of a second color, and
a third light-emitting element configured to emit light of a third color,
each of the first light-emitting element, the second light-emitting element, and the third light-emitting element includes at least one of the plurality of carrier transport layers between the first electrode and the light-emitting layer, and
the number of the carrier transport layers layered differs in the first light-emitting element, the second light-emitting element, and the third light-emitting element.

21. The light-emitting device according to claim 1, comprising:
a plurality of the light-emitting elements,
wherein the plurality of the light-emitting elements include
a first light-emitting element configured to emit light of a first color,
a second light-emitting element configured to emit light of a second color, and
a third light-emitting element configured to emit light of a third color,
each of the first light-emitting element, the second light-emitting element, and the third light-emitting element includes, between the first electrode and the light-emitting layer, an individual carrier transport layer provided for each of the light-emitting elements as one of the plurality of the carrier transport layers, and a common carrier transport layer on each of the individual carrier transport layers, the common carrier transport layer being provided in common to the first light-emitting element, the second light-emitting element, and the third light-emitting element, and
the insulating layer is provided between the individual carrier transport layer and the common carrier transport layer.

22-24. (canceled)
